(19) United States
(12) Patent Application Publication
(10) Pub. No.: US 2025/0330183 A1
(43) Pub. Date: Oct. 23, 2025

(54) DELAY-LOCKED LOOP CIRCUIT AND DELAY-LOCKED LOOP METHOD

(71) Applicants: Institute of Integrated Circuits, Henan Academy of Sciences, Zhengzhou (CN); Yellow River Electronic Technology Co., Ltd., Zhengzhou (CN)

(72) Inventor: Ningchun YIN, Zhengzhou (CN)

(21) Appl. No.: 18/791,354

(22) Filed: Jul. 31, 2024

(30) Foreign Application Priority Data
Apr. 18, 2024 (CN) 202410467569.2

(51) Int. Cl. H03L 7/081

(52) U.S. Cl. CPC H03L 7/0816

(57) ABSTRACT

A delay-locked loop circuit including: a delay distribution circuit, which delays the zeroth delay signal by a digital delay duration to generate a delay signal, delays the delay signal by a first, second reference duration, an analog delay duration to generate a first, third, second clock signals, adjust the digital, analog delay duration to obtain an adjusted analog delay duration, according to the first, second, third clock signals, output an adjusted second clock signal when the adjusted analog delay duration is within a preset duration range; a phase comparator, which performs phase comparison on the adjusted second clock signal and a reference clock signal, to generate a first, second signals; a voltage generation circuit, which generates a regulation voltage according to the first, second signals, to readjust the adjusted analog delay duration until a twice-adjusted second clock signal is synchronized with the reference clock signal.

### CROSS REFERENCE TO RELATED APPLICATION

Pursuant to 35 U.S.C. § 119 and the Paris Convention Treaty, this application claims foreign priority to Chinese Patent Application No. CN 202410467569.2 filed Apr. 18, 2024, the contents of which, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, MA 02142.

### BACKGROUND

The disclosure relates to the field of integrated circuits, and more specifically, to a delay-locked loop circuit and a delay-locked loop method.

Clock signals are widely used to synchronize the operation timing of semiconductor devices. When a clock signal generated by an external device is used for an internal circuit of a semiconductor device, the internal circuit may cause a time delay problem. Therefore, a delay-locked loop circuit is usually integrated into the semiconductor device to compensate for the time delay, so that the clock signal inside the semiconductor device is synchronized with the clock signal from the external device.

However, current delay-locked loop circuits generally use all-digital circuits to adjust the time delay. The delay duration of each delay unit in the all-digital circuits is a fixed value, which causes problems such as poor delay accuracy.

### SUMMARY

A first aspect of the disclosure provides a delay-locked loop circuit. The delay-locked loop circuit at least includes: a delay distribution circuit, configured to receive a zeroth delay signal, delay the zeroth delay signal by a digital delay duration to generate an m-th delay signal, delay the m-th delay signal by a first reference duration, an analog delay duration, and a second reference duration to correspondingly generate a first clock signal, a second clock signal, and a third clock signal, adjust the digital delay duration according to the first clock signal, the second clock signal, and the third clock signal, thereby adjusting the analog delay duration to obtain an adjusted analog delay duration, and output an adjusted second clock signal when the adjusted analog delay duration is within a preset duration range; the first reference duration is greater than the second reference duration, the preset duration range is between the second reference duration and the first reference duration; a first phase comparator, coupled to the delay distribution circuit, configured to receive the adjusted second clock signal and a reference clock signal, and perform phase comparison on the adjusted second clock signal and the reference clock signal to generate a first signal and a second signal; and a voltage generation circuit, coupled to the first phase comparator, configured to generate a regulation voltage according to the first signal and the second signal, to readjust the adjusted analog delay duration until a twice-adjusted second clock signal output from the delay distribution circuit is synchronized with the reference clock signal.

A second aspect of the disclosure provides a delay-locked loop method. The delay-locked loop method is applied to a delay-locked loop circuit; the delay-locked loop circuit includes a delay distribution circuit, a first phase comparator, and a voltage generation circuit; the delay-locked loop method includes: receiving, using the delay distribution circuit, a zeroth delay signal, delaying the zeroth delay signal by a digital delay duration to generate an m-th delay signal, delaying the m-th delay signal by a first reference duration, an analog delay duration, and a second reference duration to correspondingly generate a first clock signal, a second clock signal, and a third clock signal, and adjusting the digital delay duration according to the first clock signal, the second clock signal, and the third clock signal, thereby adjusting the analog delay duration to obtain an adjusted analog delay duration; the first reference duration is greater than the second reference duration; outputting, using the delay distribution circuit, an adjusted second clock signal when the adjusted analog delay duration is within a preset duration range; the preset duration range is between the second reference duration and the first reference duration; receiving, using the first phase comparator, the adjusted second clock signal and a reference clock signal, performing phase comparison on the adjusted second clock signal and the reference clock signal to generate a first signal and a second signal; and generating, using the voltage generation circuit, a regulation voltage according to the first signal and the second signal, to readjust the adjusted analog delay duration until a twice-adjusted second clock signal output from the delay distribution circuit is synchronized with the reference clock signal.

### BRIEF DESCRIPTION OF THE DRAWINGS

FIG. 1 shows a block diagram of a delay-locked loop circuit according to an embodiment of the disclosure.

FIG. 2A shows a block diagram of a delay distribution circuit according to an embodiment of the disclosure.

FIG. 2B shows a block diagram of a delay distribution circuit according to another embodiment of the disclosure.

FIG. 3A shows a circuit diagram of an adjustable digital delay circuit according to an embodiment of the disclosure.

FIG. 3B shows a circuit diagram of an adjustable digital delay circuit according to another embodiment of the disclosure.

FIG. 4 shows a circuit diagram of a digital delay unit according to an embodiment of the disclosure.

FIG. 5 shows a circuit diagram of a first delay reference circuit according to an embodiment of the disclosure.

FIG. 6 shows a circuit diagram of an analog delay circuit according to an embodiment of the disclosure.

FIG. 7A shows a circuit diagram of a second phase comparator according to an embodiment of the disclosure.

FIG. 7B shows a circuit diagram of a second phase comparator according to another embodiment of the disclosure.

FIG. 8 shows a circuit diagram of a reset circuit according to an embodiment of the disclosure.

FIG. 9 shows a circuit diagram of a control circuit according to an embodiment of the disclosure.

FIG. 10 shows a circuit diagram of an m-th pulse generator according to an embodiment of the disclosure.

FIG. 11 shows a timing diagram of a first clock signal CLKA′, a second clock signal CLKA, a third clock signal CLKA″, a first phase signal PH′, a second phase signal PH″, and a reset signal RESET when an analog delay duration is not greater than a second reference duration according to an embodiment of the disclosure.

FIG. 12 shows a timing diagram of a first clock signal CLKA′, a second clock signal CLKA, a third clock signal CLKA″, a first phase signal PH′, a second phase signal PH″, and a reset signal RESET when an analog delay duration is less than a first reference duration and greater than the second reference duration according to an embodiment of the disclosure.

FIG. 13 shows a timing diagram of a first clock signal CLKA′, a second clock signal CLKA, a third clock signal CLKA″, a first phase signal PH′, a second phase signal PH″, and a reset signal RESET when an analog delay duration is not less than a first reference duration according to an embodiment of the disclosure.

FIG. 14 shows a flowchart of a delay distribution method according to an embodiment of the disclosure.

FIG. 15 shows a circuit diagram of a first phase comparator and a voltage generation circuit according to an embodiment of the disclosure.

FIG. 16 shows a timing diagram of a reference clock signal CLK_REF, an adjusted second clock signal CLKB, a first signal PH_{H1}, a second signal PH_{H2}, and a reset signal RESET3 when the adjusted second clock signal CLKB is ahead of the reference clock signal CLK_REF according to an embodiment of the disclosure.

FIG. 17 shows a timing diagram of a reference clock signal CLK_REF, an adjusted second clock signal CLKB, a first signal PH_{H1}, a second signal PH_{H2}, and a reset signal RESET3 when the adjusted second clock signal CLKB lags behind the reference clock signal CLK_REF according to an embodiment of the disclosure.

FIG. 18 shows a timing diagram of a reference clock signal CLK_REF, an adjusted second clock signal CLKB, a first signal PH_{H1}, a second signal PH_{H2}, and a reset signal RESET3 when the adjusted second clock signal CLKB is synchronized with the reference clock signal CLK_REF according to an embodiment of the disclosure.

FIG. 19 shows a flowchart of a delay-locked loop method according to an embodiment of the disclosure.

### DETAILED DESCRIPTION

Reference will now be made in detail to the embodiments of the disclosure. While the disclosure will be described in combination with these embodiments, it will be understood that they are not intended to limit the invention to these embodiments. On the contrary, the disclosure is intended to cover alternatives, modifications and equivalents, which may be included within the spirit and scope of the disclosure as defined by the appended claims.

Furthermore, in the following detailed description of the disclosure, numerous specific details are set forth in order to provide a thorough understanding of the disclosure. However, it will be recognized by one of ordinary skill in the art that the disclosure may be practiced without these specific details. In other instances, well known methods, procedures, components, and circuits have not been described in detail as not to unnecessarily obscure aspects of the disclosure. The terms “connection”, “connected”, “coupled” and similar terms involved in the disclosure are not limited to physical or mechanical connections, but can include electrical connections, whether direct or indirect.

In the disclosure, the reference clock signal CLK_REF is a square wave with a fixed clock period within a certain error range.

In the disclosure, a first level can be a low level, and a second level can be a high level. It can be understood that those skilled in the art can also realize that a first level is a high level and a second level is a low level by simply replacing circuits of the disclosure.

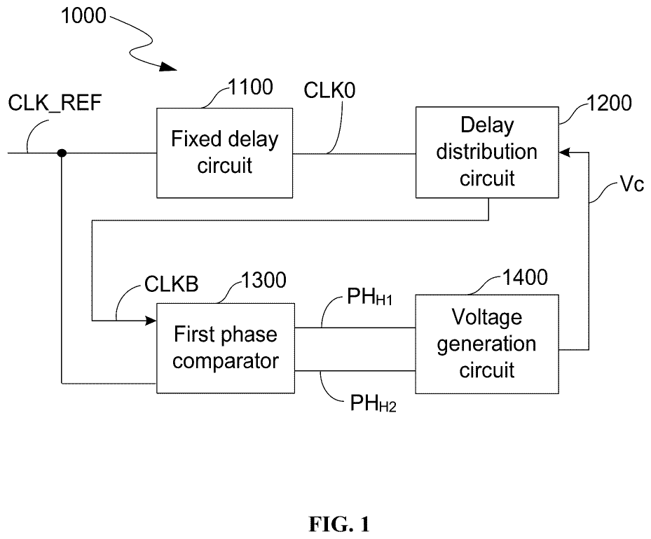

In FIG. 1, the delay-locked loop circuit 1000 at least includes a fixed delay circuit 1100, a delay distribution circuit 1200, a first phase comparator 1300, and a voltage generation circuit 1400.

The fixed delay circuit 1100 is configured to delay a reference clock signal CLK_REF by a fixed duration T_{FIX} to generate a zeroth delay signal CLK0. In an embodiment, the fixed delay circuit 1100 includes a resistor and a capacitor. A first end of the resistor receives the reference clock signal CLK_REF, a second end of the resistor is connected to a first end of the capacitor to form an output end, and a second end of the capacitor is grounded. The capacitor can be charged and discharged by the reference clock signal CLK_REF, so that the zeroth delay signal CLK0 output from the output end lags behind the reference clock signal CLK_REF by the fixed duration T_{FIX}.

The delay distribution circuit 1200 is configured to receive the zeroth delay signal CLK0, delay the zeroth delay signal CLK0 by a digital delay duration T_{DIG} to generate an m-th delay signal CLKm, delay the m-th delay signal CLKm by a first reference duration T₁, an analog delay duration T_{ANA}, and the second reference duration T₂ to correspondingly generate a first clock signal CLKA′, a second clock signal CLKA, and a third clock signal CLKA″, adjust the digital delay duration T_{DIG} according to the first clock signal CLKA′, the second clock signal CLKA, and the third clock signal CLKA″, thereby adjusting the analog delay duration T_{ANA} to obtain an adjusted analog delay duration, and output an adjusted clock signal CLKB when the adjusted analog delay duration is within a preset duration range. The first reference duration T₁ is greater than the second reference duration T₂. The first reference duration T₁ and the second reference duration T₂ are both fixed values, and the digital delay duration T_{DIG} and the analog delay duration T_{ANA} are both variable values. In an embodiment, the preset duration range is 1 ps to 120 ps. The preset duration range is between the second reference duration T₂ and the first reference duration T₁.

When the second clock signal CLKA is ahead of or synchronized with the third clock signal CLKA″, the digital delay duration T_{DIG} is reduced, thereby increasing the analog delay duration T_{ANA}. When the second clock signal CLKA is ahead of the first clock signal CLKA′ and the second clock signal CLKA lags behind the third clock signal CLKA″, the digital delay duration T_{DIG} remains unchanged so that the analog delay duration T_{ANA} also remains unchanged. When the second clock signal CLKA lags behind or is synchronized with the first clock signal CLKA′ and the second clock signal CLKA lags behind the third clock signal CLKA″, the digital delay duration T_{DIG} is increased, thereby reducing the analog delay duration T_{ANA}.

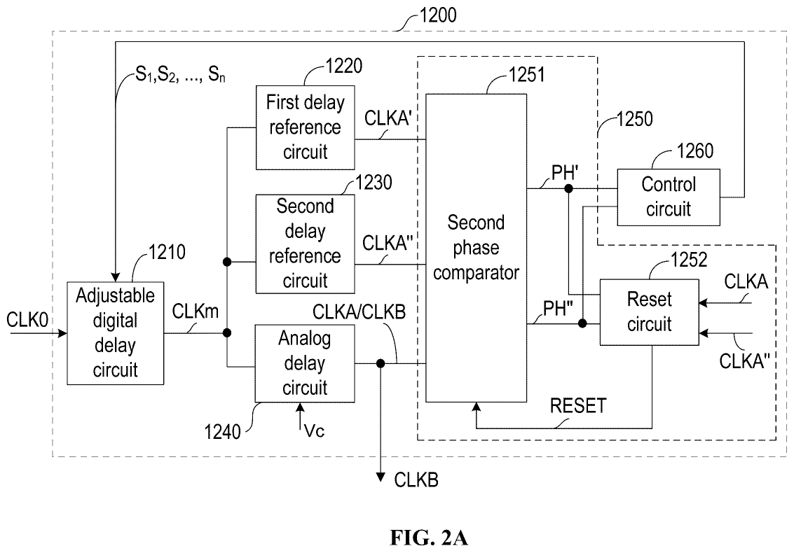

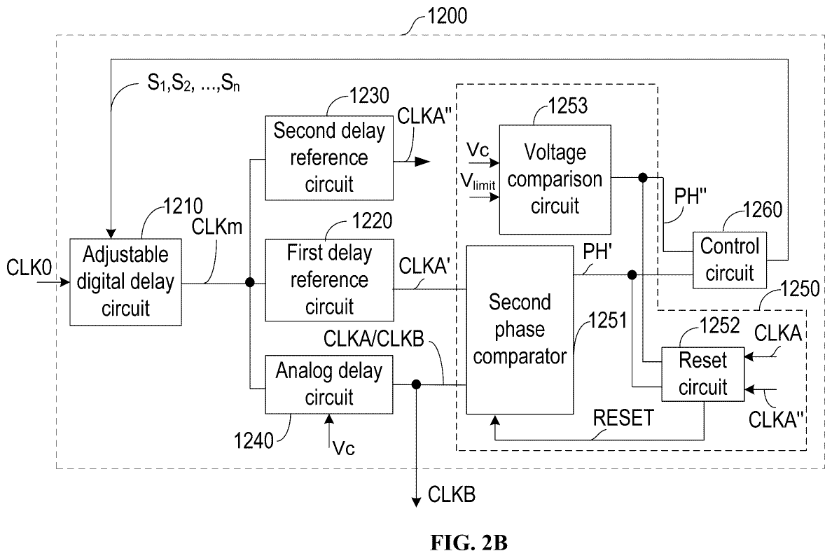

In FIG. 2A, the delay distribution circuit 1200 includes an adjustable digital delay circuit 1210, a first delay reference circuit 1220, a second delay reference circuit 1230, an analog delay circuit 1240, a phase comparison circuit 1250, and a control circuit 1260.

The adjustable digital delay circuit 1210 is configured to receive the zeroth delay signal CLK0, delay the zeroth delay signal CLK0 by m times a preset duration to generate the m-th delay signal CLKm, where the preset duration is a duration that each digital delay unit in the adjustable digital delay circuit 1210 delays received signals. The m times the preset duration is the digital delay duration T_{DIG}. The preset duration is less than the first reference duration T₁ and is greater than the second reference duration T₂. For example, when the preset duration is 100 ps, the first reference duration T₁ is 101 ps, and the second reference duration T₂ is 0.5 ps.

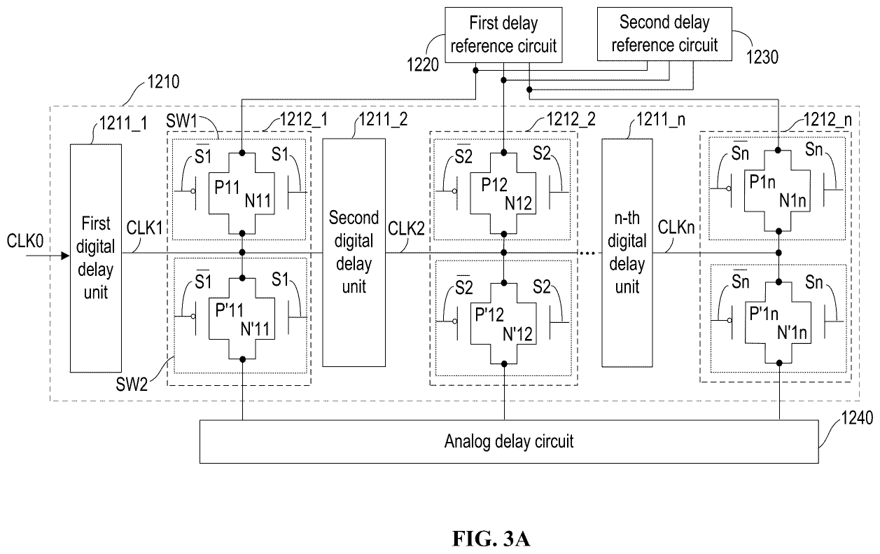

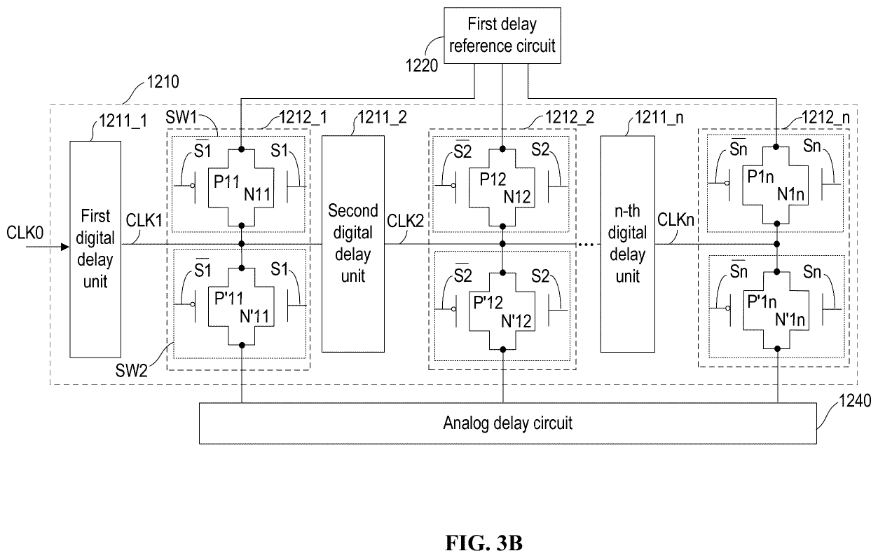

In an embodiment, in FIG. 3A or FIG. 3B, the adjustable digital delay circuit 1210 includes digital delay units 1211_1, 1211_2, . . . , 1211_n and switch circuits 1212_1, 1212_2, . . . , 1212_n, where n≥2 and n is an integer. The above digital delay units are connected in sequence, and an output end of an m-th digital delay unit 1211_m is connected to an m-th switch circuit, where 1≤m≤n and m is an integer. For example, the adjustable digital delay circuit 1210 includes the first digital delay unit 1211_1, the second digital delay unit 1211_2, the first switch circuit 1212_1, and the second switch circuit 1212_2. The first digital delay unit 1211_1 is connected to the second digital delay unit 1211_2. The first digital delay unit 1211_1 receives the zeroth delay signal CLK0. An output end of the first digital delay unit 1211_1 is connected to the first switch circuit 1212_1. An output end of the second digital delay unit 1211_2 is connected to the second switch circuit 1212_2.

Each digital delay unit delays signals it receives by the same amount of time. The disclosure takes the delay duration of each digital delay unit being the preset duration as an example. For example, in FIG. 3A, when the first switch circuit 1212_1 is turned on and other switch circuits are turned off, the first digital delay unit 1211_1 delays the zeroth delay signal CLK0 by the preset duration to generate the first delay signal CLK1 (in the disclosure, the numbers 1, 2, . . . , n following a symbol CLK are only used to distinguish which digital delay unit the delay signal is output from, and do not indicate that multiple delay signals will be simultaneously generated), and the first delay signal CLK1 is respectively transmitted to the first delay reference circuit 1220, the second delay reference circuit 1230, and the analog delay circuit 1240 in FIG. 3A through the first switch circuit 1212_1. It can be seen that the first delay signal CLK1 lags behind the zeroth delay signal CLK0 by the preset duration. For example, in FIG. 3B, when the second switch circuit 1212_2 is turned on and other switch circuits are turned off, the zeroth delay signal CLK0 becomes the second delay signal CLK2 after being delayed by the first digital delay unit 1211_1 and the second digital delay unit 1211_2, and the second delay signal CLK2 is respectively transmitted to the first delay reference circuit 1220 and the analog delay circuit 1240 in FIG. 3B through the second switch circuit 1212_2. It can be seen that the second delay signal CLK2 lags behind the zeroth delay signal CLK0 by twice the preset duration.

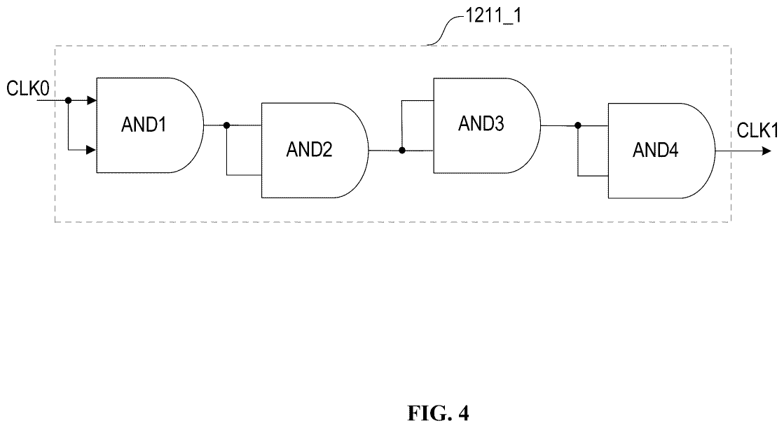

In some embodiments, as shown in FIG. 4, each digital delay unit includes AND gates AND1, AND2, AND3, and AND4 connected in sequence. For example, for the first digital delay unit 1211_1, the zeroth delay signal CLK0 becomes the first delay signal CLK1 after sequentially passing through the AND gates AND1, AND2, AND3, and AND4. Since each AND gate can delay the signals it receives by a fixed duration, the first delay signal CLK1 lags behind the zeroth delay signal CLK0 by four times the fixed duration. Four times the fixed duration is the preset duration. Of course, each digital delay unit can also include other types of logic gates (e.g., OR gates, NOT gates, etc.). Different preset duration can be determined based on the type and number of logic gates.

In an embodiment, as shown in FIG. 3A, each switch circuit includes a first branch and a second branch. The first branch of the m-th switch circuit 1212_m is coupled to the m-th digital delay unit 1211_m, the first delay reference circuit 1220, and the second delay reference circuit 1230, and the second branch of the m-th switch circuit 1212_m is coupled between the m-th digital delay unit 1211_m and the analog delay circuit 1240, where 1≤m≤n and m is an integer. Under the control of the control signals S₁, S₂, . . . , Sₙ, one of the switch circuits 1212_1, 1212_2, . . . , 1212_n is turned on. For example, if the control signal S₁ controls the first switch circuit 1212_1 to be turned on, other control signals S₂, S₃, . . . , Sₙ correspondingly control other switch circuits 1212_2, 1212_3, . . . , 1212_n to be turned off. In FIG. 3B, the first branch of the m-th switch circuit 1212_m is coupled between the m-th digital delay unit 1211_m and the first delay reference circuit 1220.

The disclosure takes the first branch SW1 and the second branch SW2 of the first switch circuit 1212_1 in FIG. 3A as an example. The first and second branches of other switch circuits, and the first and second branches of any switch circuit in FIG. 3B are similar to those of the first switch circuit 1212_1. The first branch SW1 includes a PMOS transistor P11 and an NMOS transistor N11. A drain of the PMOS transistor P11 is connected to a source of the NMOS transistor N11 to form an input end (which receives the first delay signal CLK1) of the first branch SW1, a source of the PMOS transistor P11 is connected to a drain of the NMOS transistor N11 to form an output end (which outputs the first delay signal CLK1) of the first branch SW1, a gate of the PMOS transistor P11 receives an inverted control signal S̅₁̅, and a gate of the NMOS transistor N11 receives the control signal S₁ (the control signals will be described in detail below, and S₁ and S̅₁̅ control the first switch circuit 1212_1 to be turned on/off, S₂ and S̅₂̅ control the second switch circuit 1212_2 to be turned on/off, . . . , Sₙ and S̅ₙ̅ control the n-th switch circuit 1212_n to be turned on/off). The second branch SW2 includes a PMOS transistor P′11 and an NMOS transistor N′11. A source of the PMOS transistor P′11 is connected to a drain of the NMOS transistor N′11 to form an input end (which receives the first delay signal CLK1) of the second branch SW2, a drain of the PMOS transistor P′11 is connected to a source of the NMOS transistor N′11 to form an output end (which outputs the first delay signal CLK1) of the second branch SW2, a gate of the PMOS transistor P′11 receives the inverted control signal S̅₁̅, and a gate of the NMOS transistor N′11 receives the control signal S₁. When the control signal S₁ is at a second level (e.g., a high level), the PMOS transistor P11, the NMOS transistor N11, the PMOS transistor P′11, and the NMOS transistor N′11 are all turned on, thereby enabling the first delay signal CLK1 to be transmitted to the first delay reference circuit 1220, the second delay reference circuit 1230, and the analog delay circuit 1240 in FIG. 3A. When the control signal S₁ is at a first level (e.g., a low level), the PMOS transistor P11, the NMOS transistor N11, the PMOS transistor P′11, and the NMOS transistor N′11 are all turned off, so that the first delay signal CLK1 cannot be transmitted to the first delay reference circuit 1220, the second delay reference circuit 1230, and the analog delay circuit 1240 in FIG. 3A. In other embodiments, the first and second branches can also be composed of triodes, junction field-effect transistors, etc.

The first delay reference circuit 1220 is coupled to the adjustable digital delay circuit 1210 and is configured to delay the m-th delay signal CLKm by the first reference duration T₁ to generate the first clock signal CLKA′.

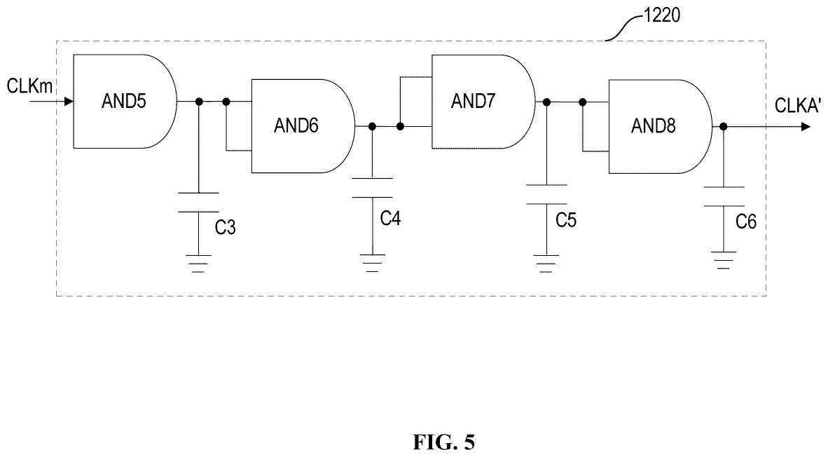

In some embodiments, as shown in FIG. 5, the first delay reference circuit 1220 includes AND gates AND5, AND6, AND7, and AND8 connected in sequence, and load capacitors C3, C4, C5, C6, and the connection relationship is as shown in FIG. 5. Since each AND gate can delay the signals it receives by a first fixed duration and each load capacitor can also delay the signals it receives by a second fixed duration, the first clock signal CLKA′ lags behind the m-th delay signal CLKm and a lag duration (the first reference duration T₁) is the sum of 4 times the first fixed duration and 4 times the second fixed duration. Compared with the preset duration of a single digital delay unit, the first reference duration T₁ is slightly greater than the preset duration because an output end of each AND gate in FIG. 5 is coupled to a load capacitor. In other embodiments, under the premise of ensuring that the first reference duration T₁ is slightly greater than the preset duration, the number of logic gates can be arbitrarily set, e.g., 3, 5, 6, etc., and the type of logic gates can also be NOT gates, OR gates, NAND gates, etc.

The second delay reference circuit 1230 is coupled to the adjustable digital delay circuit 1210, and is configured to delay the m-th delay signal CLKm by the second reference duration T₂ to generate a third clock signal CLKA″. The second reference duration T₂ can be the minimum duration that the analog delay circuit 1240 delays the signals it receives. In some embodiments, the second delay reference circuit 1230 may be realized by reducing the number of logic gates and/or load capacitors in FIG. 4 or FIG. 5.

The analog delay circuit 1240 is coupled to the adjustable digital delay circuit 1210, and is configured to delay the m-th delay signal CLKm by the analog delay duration T_{ANA} to generate the second clock signal CLKA, and readjust the adjusted analog delay duration to generate a twice-adjusted second clock signal according to the regulation voltage Vc.

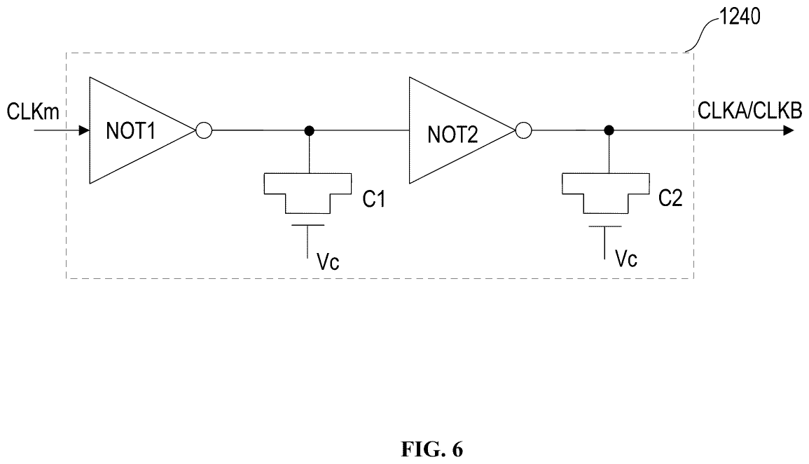

In some embodiments, as shown in FIG. 6, the analog delay circuit 1240 includes a first NOT gate NOT1, a second NOT gate NOT2, a first MOS capacitor C1, and a second MOS capacitor C2. An input end of the first NOT gate NOT1 receives the m-th delay signal CLKm, an output end of the first NOT gate NOT1 is coupled to an input end of the second NOT gate NOT2 and a first end of the first MOS capacitor C1, an output end of the second NOT gate NOT2 is coupled to a first end of the second MOS capacitor C2 to output the second clock signal CLKA, and a second end of the first MOS capacitor C1 and a second end of the second MOS capacitor C2 are coupled to a regulation voltage Vc (which will be introduced in detail below). The first MOS capacitor C1 and the second MOS capacitor C2 can be composed of PMOS transistors or NMOS transistors, for example, a source, substrate and drain of a PMOS transistor or an NMOS transistor are connected together to form the first ends of C1 and C2, and a gate of the PMOS transistor or the NMOS transistor forms the second ends of C1 and C2. The m-th delay signal CLKm becomes the second clock signal CLKA after passing through the first NOT gate NOT1, the first MOS capacitor C1, the second NOT gate NOT2, and the second MOS capacitor C2. Both the first MOS capacitor C1 and the second MOS capacitor C2 can charge and discharge according to the signals they receive, to delay the signals they receive, thereby making the second clock signal CLKA lag behind or be synchronized with the m-th delay signal CLKm. At the same time, the regulation voltage Vc can change the capacitance values of the first MOS capacitor C1 and the second MOS capacitor C2 to change the delay duration that the first MOS capacitor C1 and the second MOS capacitor C2 delay the signals, thereby adjusting the analog delay duration T_{ANA}.

The phase comparison circuit 1250 is respectively coupled to the first delay reference circuit 1220 and the analog delay circuit 1240, and is configured to generate a first phase signal PH′ and a second phase signal PH″ according to the first clock signal CLKA′, the second clock signal CLKA, and the third clock signal CLKA″. The first phase signal PH′ indicates a numerical relationship between the first reference duration T₁ and the analog delay duration T_{ANA}, the second phase signal PH″ indicates a numerical relationship between the second reference duration T₂ and the analog delay duration T_{ANA}.

When the first phase signal PH′ and the second phase signal PH″ jointly indicate that the analog delay duration T_{ANA} is not greater than the second reference duration T₂, the multiple control signals S₁, S₂, . . . , Sₙ control the number of digital delay units connected in the adjustable digital delay circuit 1210 to be reduced to reduce the digital delay duration T_{DIG}, thereby increasing the analog delay duration T_{ANA}. When the first phase signal PH′ and the second phase signal PH′ jointly indicate that the analog delay duration T_{ANA} is less than the first reference duration T₁ and greater than the second reference duration T₂, the multiple control signals S₁, S₂, . . . , Sₙ control the number of digital delay units connected in the adjustable digital delay circuit 1210 to remain unchanged, to make the digital delay duration T_{DIG} remain unchanged, thereby making the analog delay duration T_{ANA} also remain unchanged. When the first phase signal PH′ and the second phase signal PH″ jointly indicate that the analog delay duration T_{ANA} is not less than the first reference duration T₁, the multiple control signals S₁, S₂, . . . , Sₙ control the number of digital delay units connected in the adjustable digital delay circuit 1210 to be increased to increase the digital delay duration T_{DIG}, thereby reducing the analog delay duration T_{ANA}.

In some embodiments, as shown in FIG. 2A, the phase comparison circuit 1250 includes a second phase comparator 1251 and a reset circuit 1252. The second phase comparator 1251 is respectively coupled to the first delay reference circuit 1220, the second delay reference circuit 1230, and the analog delay circuit 1240, and the reset circuit 1252 is coupled to the second phase comparator 1251. The second phase comparator 1251 is configured to control the first phase signal PH′ or the second phase signal PH″ to perform a first level conversion according to a phase relationship between the first clock signal CLKA′ and the second clock signal CLKA, and/or a phase relationship between the second clock signal CLKA and the third clock signal CLKA″. The reset circuit 1252 is configured to generate the reset signal RESET to control the first phase signal PH′ or the second phase signal PH″ to perform a second level conversion according to the first phase signal PH′, the second phase signal PH″, the second clock signal CLKA, and the third clock signal CLKA″.

Under a condition that the second clock signal CLKA is ahead of or synchronized with the third clock signal CLKA″, the second phase signal PH″ jumps from a first level to a second level when a first rising edge of the second clock signal CLKA arrives, and the reset signal RESET jumps from a first level to a second level when a first rising edge of the third clock signal CLKA″ arrives, thereby controlling the second phase signal PH″ to jump from a second level to a first level. Under a condition that the second clock signal CLKA is ahead of the first clock signal CLKA′ and the second clock signal CLKA lags behind the third clock signal CLKA″, the first phase signal PH′, the second phase signal PH″, and the reset signal RESET are always at a first level. Under a condition that the second clock signal CLKA lags behind or is synchronized with the first clock signal CLKA′ and the second clock signal CLKA lags behind the third clock signal CLKA″, the first phase signal PH′ jumps from a first level to a second level when a first rising edge of the first clock signal CLKA′ arrives, and the reset signal RESET jumps from a first level to a second level when a first rising edge of the second clock signal CLKA arrives, thereby controlling the first phase signal PH′ to jump from a second level to a first level.

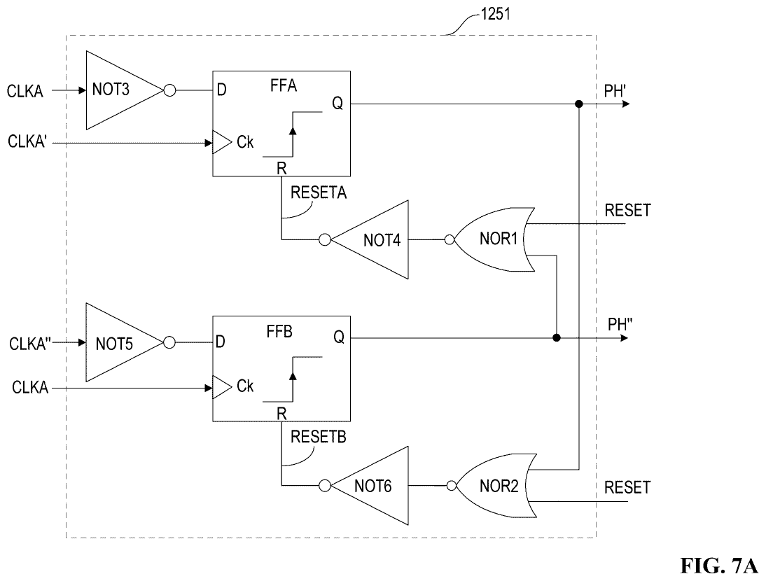

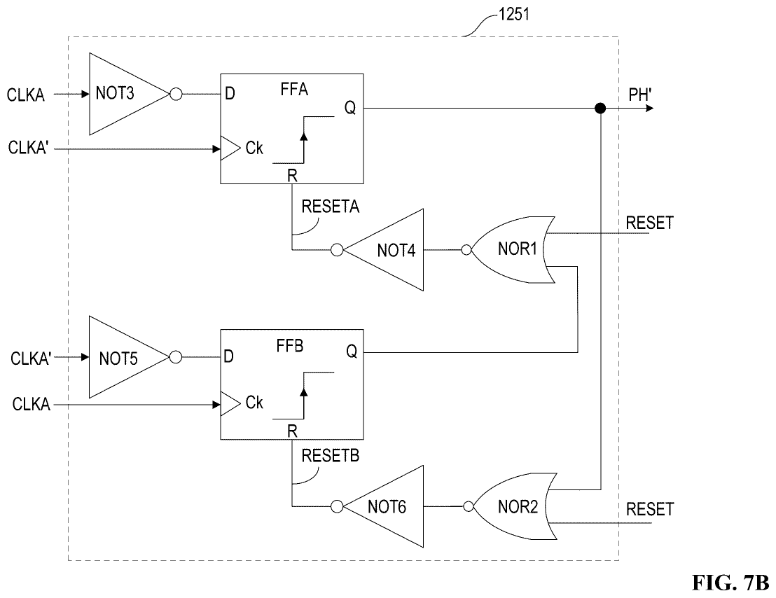

In some embodiments, as shown in FIG. 7A, the second phase comparator 1251 includes a first flip-flop FFA, a third NOT gate NOT3, a fourth NOT gate NOT4, a first NOR gate NOR1, a second flip-flop FFB, a fifth NOT gate NOT5, a sixth NOT gate NOT6, and a second NOR gate NOR2. An input end of the third NOT gate NOT3 receives the second clock signal CLKA, an output end of the third NOT gate NOT3 is coupled to an input end D of the first flip-flop FFA, a clock end Ck of the first flip-flop FFA receives the first clock signal CLKA′, an output end Q of the first flip-flop FFA is coupled to the reset circuit 1252 to output the first phase signal PH′ to the reset circuit 1252, a first input end of the second NOR gate NOR2 is coupled to an output end Q of the first flip-flop FFA, a second input end of the second NOR gate NOR2 is coupled to the reset circuit 1252 to receive the reset signal RESET generated by the reset circuit 1252, an output end of the second NOR gate NOR2 is coupled to an input end of the sixth NOT gate NOT6, an output end of the sixth NOT gate NOT6 is coupled to a reset end R of the second flip-flop FFB, an input end of the fifth NOT gate NOT5 receives the third clock signal CLKA″, an output end of the fifth NOT gate NOT5 is coupled to an input end D of the second flip-flop FFB, a clock end Ck of the second flip-flop FFB receives the second clock signal CLKA, an output end Q of the second flip-flop FFB is coupled to the reset circuit 1252 to output the second phase signal PH″ to the reset circuit 1252, an first input end of the first NOR gate NOR1 is coupled to an output end Q of the second flip-flop FFB, a second input end of the first NOR gate NOR1 is coupled to the reset circuit 1252 to receive the reset signal RESET generated by the reset circuit 1252, an output end of the first NOR gate NOR1 is coupled to an input end of the fourth NOT gate NOT4, an output end of the fourth NOT gate NOT4 is coupled to a reset end R of the first flip-flop FFA. The working principle of the second phase comparator 1251 will be described below.

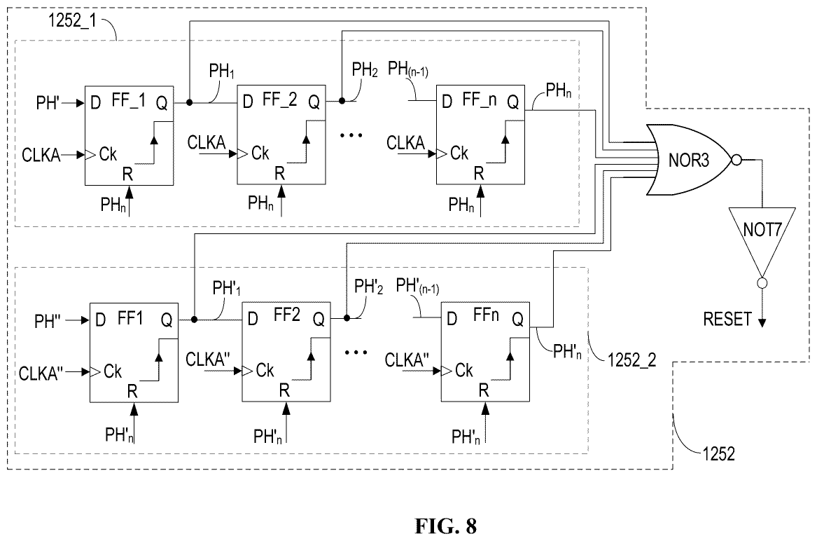

In some embodiments, as shown in FIG. 8, the reset circuit 1252 includes a first set of flip-flops 1252_1, a second set of flip-flops 1252_2, a third NOR gate NOR3, and a seventh NOT gate NOT7. The first set of flip-flops 1252_1 includes flip-flops FF_1, FF_2, . . . , FF_n connected in sequence, where n≥2 and n is an integer. The second set of flip-flops 1252_2 includes flip-flops FF1, FF2, . . . , FFn connected in sequence, where n≥2 and n is an integer. In the first set of flip-flops 1252_1, an input end D of the first flip-flop FF_1 receives the first phase signal PH′, a clock end Ck of the first flip-flop FF_1 receives the second clock signal CLKA, an output end Q of the first flip-flop FF_1 is coupled to an input end D of the second flip-flop FF_2 to output a signal PH₁, a clock end Ck of the second flip-flop FF_2 receives the second clock signal CLKA, . . . , an output end Q of the (n−1)-th flip-flop FF_(n−1) is coupled to an input end D of the n-th flip-flop FF_n to output a signal PH₍ₙ₋₁₎, a clock end Ck of the n-th flip-flop FF_n receives the second clock signal CLKA, an output end Q of the n-th flip-flop FF_n is coupled to reset ends R of the flip-flops FF_1, FF_2, . . . , FF_n to output a signal PHₙ. In the second set of flip-flops, an input end D of the first flip-flop FF1 receives the second phase signal PH″, a clock end Ck of the first flip-flop FF1 receives the third clock signal CLKA″, an output end Q of the flip-flop FF1 is coupled to an input end D of the flip-flop FF2 to output a signal PH′₁, a clock end Ck of the second flip-flop FF2 receives the third clock signal CLKA″, . . . , an output end Q of the (n−1)-th flip-flop FF(n−1) is coupled to an input end D of the n-th flip-flop FFn to output a signal PH′₍ₙ₋₁₎, a clock end Ck of flip-flop FFn receives the third clock signal CLKA″, an output end Q of the n-th flip-flop FFn is coupled to reset ends R of the flip-flops FF1, FF2, . . . , FFn to output a signal PH′n. The output ends Q of the flip-flops FF_1, FF_2, . . . , FF_n and the output ends Q of the flip-flops FF1, FF2, . . . , FFn are coupled to an input end D of the third NOR gate NOR3, an output end of the third NOR gate NOR3 is coupled to an input end of the seventh NOT gate NOT7, an output end of the NOT gate NOT7 outputs the reset signal RESET. The flip-flops FF_1, FF_2, . . . , FF_n are sequentially triggered at the multiple rising edges of the second clock signal CLKA, for example, the first flip-flop FF_1 is triggered at the first rising edge of the second clock signal CLKA, the second flip-flop FF_2 is triggered at the second rising edge of the second clock signal CLKA, . . . , the n-th flip-flop FF_n is triggered at the n-th rising edge of the second clock signal CLKA. The flip-flops FF1, FF2, . . . , FFn are sequentially triggered at the multiple rising edges of the third clock signal CLKA″. In actual circuit design, the number of flip-flops in the reset circuit 1252 can be set according to actual needs, e.g., 3, 6, etc.

The numerical relationship between the analog delay duration T_{ANA}, and the first and second reference voltages T₁, T₂ is as follows:

In the first case, the analog delay duration T_{ANA} is not greater than the second reference duration T₂, which indicates that the second clock signal CLKA is ahead of or synchronized with the third clock signal CLKA″.

In the second case, the analog delay duration T_{ANA} is less than the first reference duration T₁ and greater than the second reference duration T₂, which indicates that the second clock signal CLKA is ahead of the first clock signal CLKA′ and the second clock signal CLKA lags behind the third clock signal CLKA″.

In the third case, the analog delay duration T_{ANA} is not less than the first reference duration T₁, which indicates that the second clock signal CLKA lags behind or is synchronized with the first clock signal CLKA′ and the second clock signal CLKA lags behind the third clock signal CLKA″.

The working principle of the phase comparison circuit 1250 in FIG. 2A is as follows:

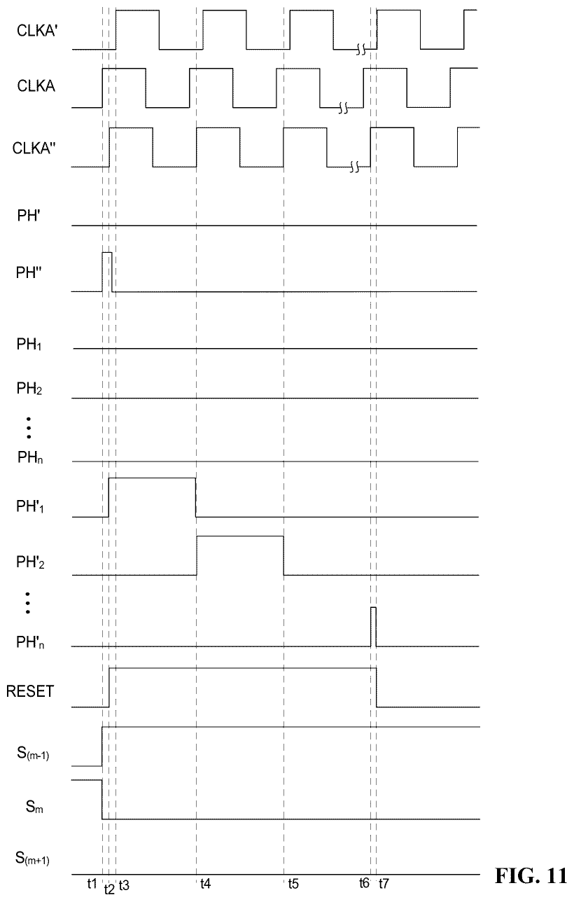

For the above first case: the timing diagram of each signal is as shown in FIG. 11.

Before time t1, the first phase signal PH′, the second phase signal PH″, the signals PH₁, PH₂, . . . , PHₙ, the signals PH′₁, PH′₂, . . . , PH′ₙ, and the reset signal RESET are all at a low level.

At time t1, a first rising edge of the second clock signal CLKA arrives, the second flip-flop FFB is triggered. At this time, the third clock signal CLKA″ at a low level becomes a high-level signal after passing through the fifth NOT gate NOT5. The high-level signal is input into an input end D of the second flip-flop FFB to make the second phase signal PH″ output from the second flip-flop FFB jump from a low level to a high level.

At time t2, a first rising edge of the third clock signal CLKA arrives, the flip-flop FF1 in the reset circuit 1252 is triggered. At this time, the second phase signal PH″ at a high level is input to the flip-flop FF1 to make the signal PH′₁ output from the flip-flop FF1 jump from a low level to a high level. Since the second, . . . , and n-th rising edges of the third clock signal CLKA″ do not arrive, the flip-flops FF2, . . . , FFn are not triggered, so the signals PH′₂ . . . , PH′ₙ continue to be at a low level. At the same time, since the second phase signal PH″ jumps from a low level to a high level, no matter what level state the reset signal RESET in FIG. 7A is in, the reset signal RESETA in FIG. 7A jumps from a low level to a high level, so that the first phase signal PH′ continues to be at a low level. Since the first phase signal PH′ continues to be at a low level, the signals PH₁, PH₂, . . . , PHₙ also continue to be at a low level. The high-level signal PH′₁, the low-level signals PH′₂, . . . , PH′ₙ, and the low-level signals PH₁, PH₂, . . . , PHₙ become the reset signal RESET at a high level (that is, the reset signal RESET jumps from a low level to a high level) after passing through the third NOR gate NOR3 and the seventh NOT gate NOT7. When the reset signal RESET jumps from a low level to a high level, the reset signal RESETB in FIG. 7A also jumps from a low level to a high level to make the second phase signal PH″ subsequently jump from a high level to a low level.

At time t3, the first rising edge of the first clock signal CLKA′ arrives, the first flip-flop FFA is triggered. However, since the signal received by the input end D of the first flip-flop FFA is at a low level, the first phase signal PH′ output from the first flip-flop FFA continues to be at a low level, thereby making the signals PH₁, PH₂, . . . , PHₙ continue to be at a low level.

At time t2, t4, t5, . . . , t6, the flip-flops FF1, FF2, . . . , FFn are also triggered in sequence, that is, the signal PH′₁ is at a high level from time t2 to time t4, the signal PH′₂ is at a high level from time t4 to time t5, . . . , the signal PH′ₙ is at a high level from time t6 to time t7.

At time t6, when the signal PH′ₙ jumps from a low level to a high level, the flip-flops FF1, FF2, . . . , FFn are all reset to make the signal PH′n jump from a high level to a low level at time t7, thereby making the reset signal RESET also jump from a high level to a low level. Subsequently, when the next rising edge of the second clock signal CLKA arrives, the phase comparison circuit 1250 starts to perform the next phase comparison.

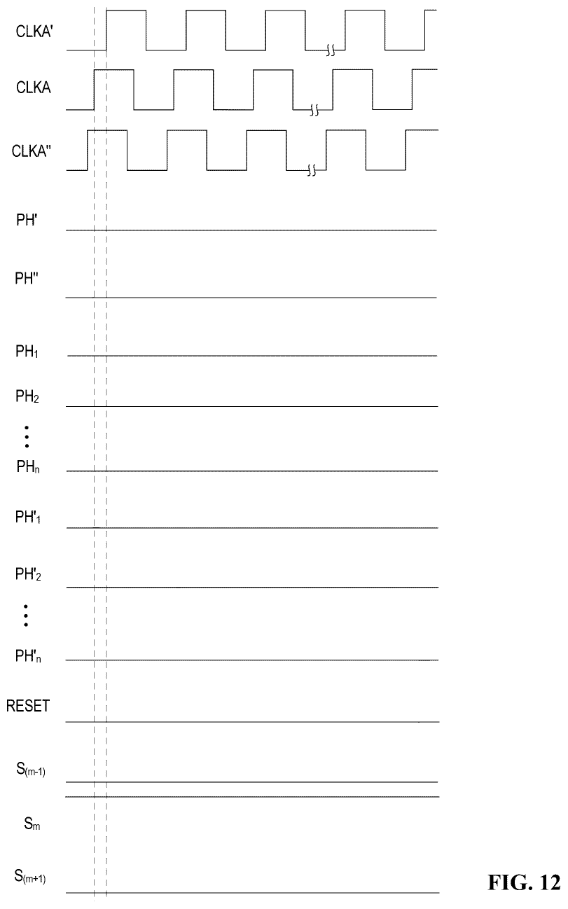

For the above second case: the timing diagram of each signal is as shown in FIG. 12. In this case, both the first phase signal PH′ and the second phase signal PH″ are always at a low level.

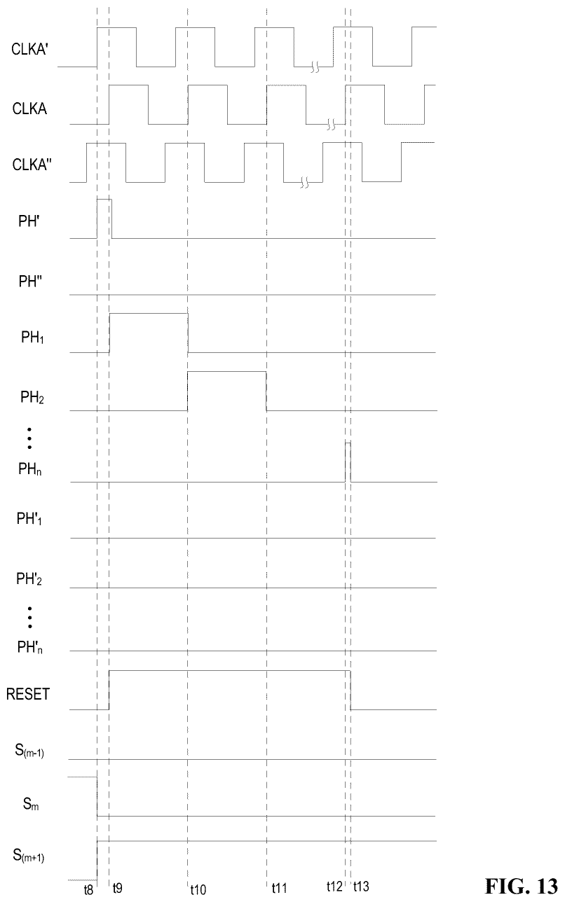

For the above third case: the timing diagram of each signal is as shown in FIG. 13.

Before time t8, the first phase signal PH′, the second phase signal PH″, the signals PH₁, PH₂, . . . , PHₙ, the signals PH′₁, PH′₂, . . . , PH′ₙ, and the reset signal RESET are all at a low level.

At time t8, a first rising edge of the first clock signal CLKA′ arrives, the first flip-flop FFA is triggered. At this time, the second clock signal CLKA at a low level becomes a high-level signal after passing through the third NOT gate NOT3, and the high-level signal is input into an input end D of the first flip-flop FFA to make the first phase signal PH′ jump from a low level to a high level.

At time t9, a first rising edge of the second clock signal CLKA arrives, the flip-flop FF_1 is triggered. At this time, the first phase signal PH′ at a high level is input to the flip-flop FF_1 to make the signal PH₁ jump from a low level to a high level. Since the second, . . . , and n-th rising edges of the second clock signal CLKA do not arrive, the flip-flops FF2, . . . , FFn are not triggered, so the signals PH₂ . . . , PHₙ all continue to be at a low level. At the same time, since the first phase signal PH′ jumps from a low level to a high level, no matter what level state the reset signal RESET in FIG. 7A is in, the reset signal RESETB jumps from a low level to a high level, so that the second phase signal PH″ continues to be at a low level. Since the second phase signal PH″ continues to be at a low level, the signals PH′₁, PH′₂, . . . , PH′ₙ also continue to be at a low level. The high-level signal PH₁, the low-level signals PH₂, . . . , PHₙ, and the low-level signals PH′₁, PH′₂, . . . , PH′ₙ become the reset signal RESET at a high level (that is, the reset signal RESET jumps from a low level to a high level) after passing through the third NOR gate NOR3 and the seventh NOT gate NOT7. When the reset signal RESET jumps from a low level to a high level, the reset signal RESETA in FIG. 7A also jumps from a low level to a high level to make the first phase signal PH′ subsequently jump from a high level to a low level.

At time t9, t10, t11, . . . , t12, the flip-flops FF_1, FF_2, . . . , FF_n are triggered in sequence, that is, the signal PH₁ is at a high level from time t9 to time t10, the signal PH₂ is at a high level from time t10 to time t11, . . . , the signal PHₙ is at a high level from time t12 to time t13.

At time t12, when the signal PHₙ jumps from a low level to a high level, the flip-flops FF_1, FF_2, . . . , FF_n are all reset to make the signal PHₙ jump from a high level to a low level at time t13, thereby making the reset signal RESET also jump from a high level to a low level. Subsequently, when the next rising edge of the first clock signal CLKA′ arrives, the phase comparison circuit 1250 starts to perform the next phase comparison.

In other embodiments, as shown in FIG. 2B, the phase comparison circuit 1250 includes a second phase comparator 1251, a reset circuit 1252, and a voltage comparison circuit 1253. The second phase comparator 1251 is coupled to the first delay reference circuit 1220 and the analog delay circuit 1240, and is configured to control the first phase signal PH′ to perform a first level conversion according to the phase relationship of the first clock signal CLKA′ and the second clock signal CLKA. The voltage comparison circuit 1253 is configured to receive the regulation voltage Vc and a limit voltage Vₗᵢₘᵢₜ, compare the regulation voltage Vc and the limit voltage Vₗᵢₘᵢₜ to generate the second phase signal PH″. The limit voltage Vₗᵢₘᵢₜ indicates the minimum duration (i.e., the second reference duration T₂) that the analog delay circuit 1240 delays received signals, and the regulation voltage Vc indicates the magnitude of the analog delay duration T_{ANA}. When the regulation voltage Vc is not greater than the limit voltage Vₗᵢₘᵢₜ, the second phase signal PH″ jumps from a first level to a second level. When the regulation voltage Vc is greater than the limit voltage Vₗᵢₘᵢₜ, the second phase signal PH″ continues to be at a first level. The reset circuit 1252 is coupled to the second delay reference circuit 1230, the analog delay circuit 1240, the second phase comparator 1251, and the voltage comparison circuit 1253, and is configured to generate a reset signal RESET to control the first phase signal PH′ to perform a second level conversion according to the second clock signal CLKA, the third clock signal CLKA″, the first phase signal PH′, and the second phase signal PH″.

Under a condition that the first clock signal CLKA′ is ahead of or synchronized with the second clock signal CLKA, the first phase signal PH′ jumps from a first level to a second level when a first rising edge of the first clock signal CLKA′ arrives, and the reset signal RESET jumps from a first level to a second level when a first rising edge of the second clock signal CLKA arrives, thereby controlling the first phase signal PH′ to jump from a second level to a first level. Under a condition that the first clock signal CLKA′ lags behind the second clock signal CLKA, the first phase signal PH′ and the reset signal RESET are always at a first level.

In some embodiments, as shown in FIG. 7B, the second phase comparator 1251 includes a first flip-flop FFA, a third NOT gate NOT3, a fourth NOT gate NOT4, a first NOR gate NOR1, a second flip-flop FFB, a fifth NOT gate NOT5, a sixth NOT gate NOT6, and a second NOR gate NOR2. An input end of the third NOT gate NOT3 receives the second clock signal CLKA, an output end of the third NOT gate NOT3 is coupled to an input end D of the first flip-flop FFA, a clock end Ck of the first flip-flop FFA receives the first clock CLKA′, an output end Q of the first flip-flop FFA is coupled to the reset circuit 1252 to output the first phase signal PH′ to the reset circuit 1252, a first input end of the second NOR gate NOR2 is coupled to an output end Q of the first flip-flop FFA, a second input end of the second NOR gate NOR2 is coupled to the reset circuit 1252 to receive the reset signal RESET generated by the reset circuit 1252, an output end of the second NOR gate NOR2 is coupled to an input end of the sixth NOT gate NOT6, an output end of the sixth NOT gate NOT6 is coupled to a reset end R of the second flip-flop FFB, an input end of the fifth NOT gate NOT5 receives the first clock signal CLKA′, an output end of the fifth NOT gate NOT5 is coupled to an input end D of the second flip-flop FFB, a clock end Ck of the second flip-flop FFB receives the second clock signal CLKA, an first input end of the first NOR gate NOR1 is coupled to an output end Q of the second flip-flop FFB, a second input end of the first NOR gate NOR1 is coupled to the reset circuit 1252 to receive the reset signal RESET generated by the reset circuit 1252, an output end of the first NOR gate NOR1 is coupled to an input end of the fourth NOT gate NOT4, an output end of the fourth NOT gate NOT4 is coupled to a reset end R of the first flip-flop FFA.

It can be seen that the difference between the second phase comparator 1251 in FIG. 7B and the second phase comparator 1251 in FIG. 7A is that the output end Q of the second flip-flop FFB in FIG. 7B no longer outputs the second phase signal PH″ to the reset circuit 1252, and the NOT gate NOT5 in FIG. 7B receives the first clock signal CLKA′ while the NOT gate NOT5 in FIG. 7A receives the third clock signal CLKA″ Therefore, the difference in working principle lies in the different sources of the second phase signal PH″, that is, the second phase signal PH″ in FIG. 2A is generated by the second flip-flop FFB in FIG. 7A, while the second phase signal PH″ in FIG. 2B is generated by the voltage comparison circuit 1253. In addition, since the reset circuit 1251 in FIG. 2A and the reset circuit 1251 in FIG. 2B are both implemented by the circuit shown in FIG. 8, the working principle of the phase comparison circuit 1250 in FIG. 2B is similar to the working principle of the phase comparison circuit 1250 in FIG. 2A.

The control circuit 1260 is coupled between the phase comparison circuit 1250 and the adjustable digital delay circuit 1210, and is configured to generate multiple control signals S₁, S₂, . . . , Sₙ based on the first phase signal PH′ and the second phase signal PH″. The multiple control signals S₁, S₂, . . . , Sₙ control the number of digital delay units connected in the adjustable digital delay circuit 1210 to adjust the digital delay duration T_{DIG}.

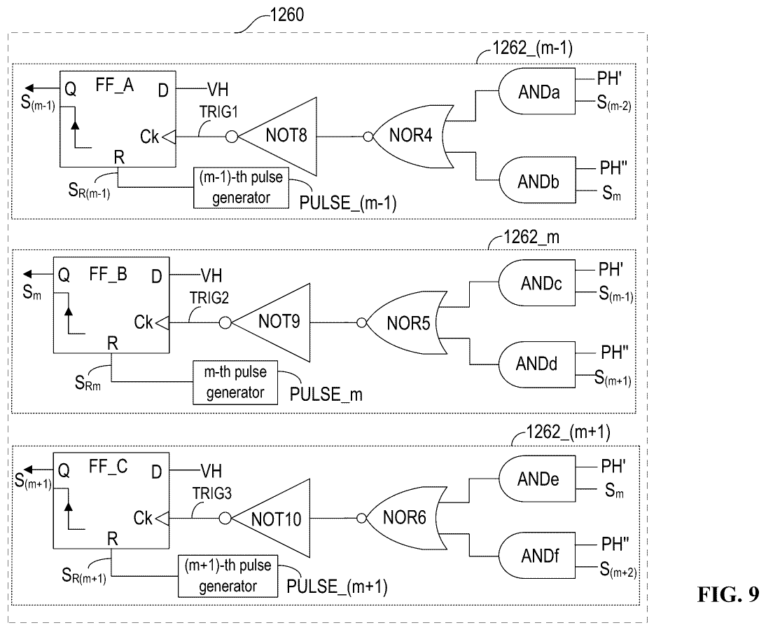

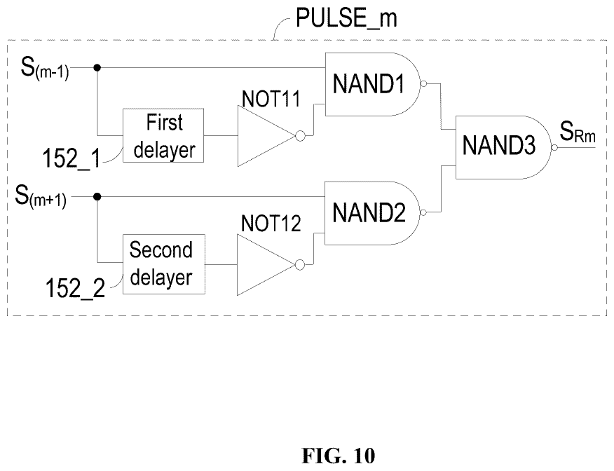

In an embodiment, the control circuit 1260 includes multiple control units. Each control unit has the same configuration. In FIG. 9, the m-th control unit 1262_m includes AND gates ANDc, ANDd, an NOR gate NOR5, a NOT gate NOT9, a flip-flop FF_B, and an m-th pulse generator PULSE_m. An input end of the AND gate ANDc receives the first phase signal PH′ and the (m−1)-th control signal S₍ₘ₋₁₎, an input end of the AND gate ANDd receives the second phase signal PH″ and the (m+1)-th control signal S₍ₘ₊₁₎, an output end of the AND gate ANDc and an output end of the AND gate ANDd are coupled to two input ends of the NOR gate NOR5, an output end of the NOR gate NOR5 is coupled to an input end of the NOT gate NOT9, an output end of the NOT gate NOT9 is coupled to an clock end Ck of the flip-flop FF_B, an input end D of the flip-flop FF_B receives a high level (e.g., a power supply voltage VH), an output end Q of the flip-flop FF_B outputs the m-th control signal Sₘ, a reset end R of the flip-flop FF_B is coupled to the m-th pulse generator PULSE_m. As shown in FIG. 10, the m-th pulse generator PULSE_m includes a first delayer 152_1, a second delayer 152_2, a NOT gate NOT11, a NOT gate NOT12, a first NAND gate NAND1, a second NAND gate NAND2, and a third NAND gate NAND3. A first input end of the first NAND gate NAND1 receives the (m−1)-th control signal S₍ₘ₋₁₎, a second input end of the first NAND gate NAND1 receives a first logic signal; a first input end of the second NAND gate NAND2 receives the (m+1)-th control signal S₍ₘ₊₁₎, a second input end of the second NAND gate NAND2 receives a second logic signal, the two input ends of the third NAND gate NAND3 are coupled to an output end of the first NAND gate NAND1 and an output end of the second NAND gate NAND2, and an output end of the third NAND gate NAND3 outputs a pulse signal S_{Rm}. The (m−1)-th control signal S₍ₘ₋₁₎ becomes the first logic signal after passing through the first delayer 152_1 and the NOT gate NOT11 in sequence, and the (m+1)-th control signal S₍ₘ₊₁₎ becomes the second logic signal after passing through the second delayer 152_2 and the NOT gate NOT12 in sequence.

The disclosure takes any three adjacent control units (the (m−1)-th control unit 1262_(m−1), the m-th control unit 1262_m, and the (m+1)-th control unit 1262_(m+1)) as an example to illustrate how the level state of the control signals changes. The specific connection relationship of the (m−1)-th control unit 1262_(m−1), the m-th control unit 1262_m, and the (m+1)-th control unit 1262_(m+1) is as shown in FIG. 9 and FIG. 10.

It is assumed that in an initial state, the control signal Smis at a high level, the control signal S₍ₘ₋₁₎ and the control signal S₍ₘ₊₁₎ are at a low level.

For the above first case, as shown in FIG. 11, at time t1, the second phase signal PH″ jumps from a low level to a high level, then a signal output from the AND gate ANDb in FIG. 9 jumps from a low level to a high level, then a signal output from NOR gate NOR4 jumps from a high level to a low level, then a trigger signal TRIG1 output from the NOT gate NOT8 jumps from a low level to a high level. When the trigger signal TRIG1 jumps from a low level to a high level, the flip-flop FF_A is triggered to make the control signal S₍ₘ₋₁₎ jump from a low level to a high level. When the control signal S₍ₘ₋₁₎ jumps from a low level to a high level, the NAND gate NAND1 in FIG. 10 output a first negative pulse signal. Since the control signal S₍ₘ₊₁₎ continues to be at a low level, the NAND gate NAND2 continues to output a high-level signal. The high-level signal and the first negative pulse signal become a pulse signal S_{Rm} with an upward pulse (i.e., a positive pulse signal) after passing through the NAND gate NAND3. The flip-flop FF_B can be reset (since the positive pulse of the pulse signal S_{Rm} lasts for a short time, the flip-flop FF_B is momentarily reset) by the pulse signal S_{Rm} with the upward pulse that is, the control signal Sₘ jumps from a high level to a low level. It can be seen that in this case, at time t1, the control signal Sₘ jumps from a high level to a low level, the control signal S₍ₘ₋₁₎ jumps from a low level to a high level, and the control signal S₍ₘ₊₁₎ continues to be at a low level. So far, the number of connected digital delay units is changed from m to (m−1).

For the above second case, as shown in FIG. 12, since neither the first phase signal PH′ nor the second phase signal PH″ has a level conversion, the control signal Sₘ continues to be at a high level, and both the control signal S₍ₘ₋₁₎ and the control signal S (m+1) continue to be at a low level, that is, the number of connected digital delay units continues to be m.

For the above third case, as shown in FIG. 13, at time t8, the first phase signal PH′ jumps from a low level to a high level, then a signal output from the AND gate ANDe in FIG. 9 jumps from a low level to a high level, a signal output from NOR gate NOR6 jumps from a high level to a low level, a trigger signal TRIG3 output from the NOT gate NOT10 jumps from a low level to a high level. When the trigger signal TRIG3 jumps from a low level to a high level, the flip-flop FF_C is triggered to make the control signal S₍ₘ₊₁₎ jump from a low level to a high level. When the control signal S₍ₘ₊₁₎ jumps from a low level to a high level, the NAND gate NAND2 in FIG. 10 outputs a second negative pulse signal. Since the control signal S₍ₘ₋₁₎ continues to be at a low level, the NAND gate NAND1 continues to output a high-level signal. The high-level signal and the second negative pulse signal become the pulse signal S_{Rm} with an upward pulse (i.e., a positive pulse signal) after passing through the NAND gate NAND3. The flip-flop FF_B can be reset (since the positive pulse of the pulse signal S_{Rm} lasts for a short time, the flip-flop FF_B is only reset briefly) by the pulse signal S_{Rm}, that is, the control signal Sₘ jumps from a high level to a low level. It can be seen that in this case, at time t8, the control signal Sₘ jumps from a high level to a low level, the control signal S₍ₘ₊₁₎ jumps from a low level to a high level, and the control signal S₍ₘ₋₁₎ continues to be at a low level. So far, the number of connected digital delay units is changed from m to (m+1).

In summary, the working principle of the delay distribution circuit 1200 is as follows:

In an initial state, it is assumed that the control signal Sₘ is at a high level and other control signals are at a low level, so that the m-th switch circuit 1212_m is turned on and other switch circuits are turned off. The zeroth delay signal CLK0 becomes the m-th delay signal CLKm after passing through m digital delay units. The m digital delay units delay the zeroth delay signal CLK0 by m times the preset duration.

The first delay reference circuit 1220 delays the m-th delay signal CLKm by the first reference duration T₁ to generate the first clock signal CLKA′. The first reference duration T₁ is slightly greater than the preset duration.

The analog delay circuit 1240 delays the m-th delay signal CLKm by the analog delay duration T_{ANA} to generate the second clock signal CLKA.

The second delay reference circuit 1230 delays the m-th delay signal CLKm by the second reference duration T₂ to generate the third clock signal CLKA″. The second reference duration T₂ is less than the preset duration.

The phase comparison circuit 1250 in FIG. 2A generates the first phase signal PH′ and the second phase signal PH″ according to the first clock signal CLKA′, the second clock signal CLKA, and the third clock signal CLKA″

If the first phase signal PH′ and the second phase signal PH″ are as shown in FIG. 13, the number of digital delay units connected in the adjustable digital delay circuit 1210 changes from m to (m+1). The (m+1) digital delay units delay the zeroth delay signal CLK0 by (m+1) times the preset duration to generate the (m+1)th delay signal CLK(m+1).

The first delay reference circuit 1220 delays the (m+1)-th delay signal CLK(m+1) by the first reference duration T₁ to generate the adjusted first clock signal.

The analog delay circuit 1240 delays the (m+1)-th delay signal CLK(m+1) by the adjusted analog delay duration to generate the adjusted second clock signal CLKB. The adjusted analog delay duration is the sum of the analog delay duration T_{ANA} and the preset duration.

The second delay reference circuit 1230 delays the (m+1)-th delay signal CLK(m+1) by the second reference duration T₂ to generate the adjusted third clock signal.

The phase comparison circuit 1250 in FIG. 2A generates the adjusted first phase signal and the adjusted second phase signal according to the adjusted first clock signal, the adjusted second clock signal CLKB, and the adjusted third clock signal. If the adjusted first phase signal and the adjusted second phase signal are as shown in FIG. 12, the adjusted analog delay duration is within the preset duration range, so the number of digital delay units connected in the adjustable digital delay circuit 1210 continues to be (m+1). Therefore, the analog delay circuit 1240 outputs the adjusted second clock signal CLKB.

The above embodiment describes that after one adjustment (e.g., increasing the number of digital delay units connected in the adjustable digital delay circuit 1210), the analog delay duration can be within the preset duration range. In other embodiments, multiple adjustments (increasing or decreasing the number of digital delay units connected in the adjustable digital delay circuit 1210) may be required to achieve the adjusted analog delay duration within the preset duration range.

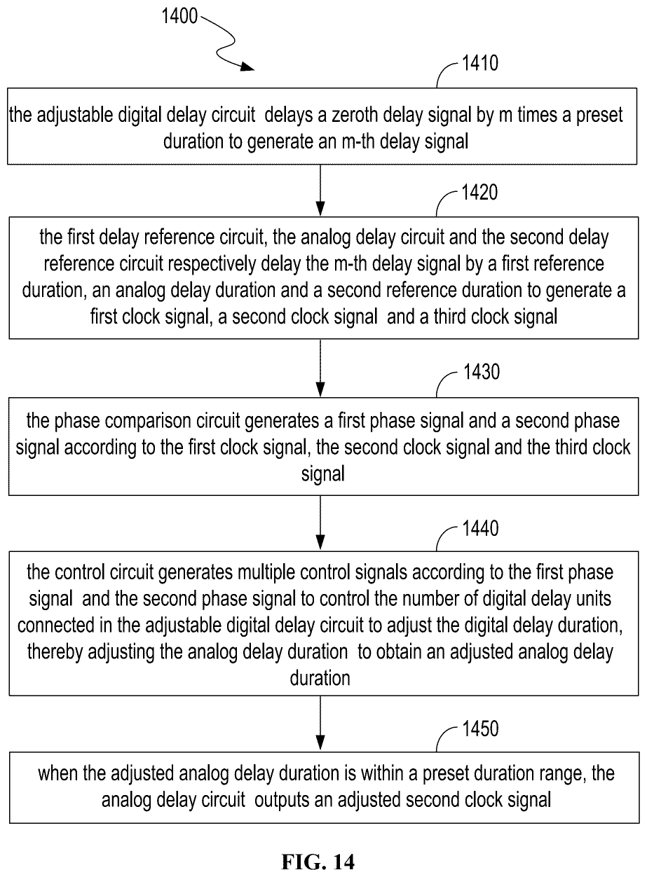

As shown in FIG. 14, the disclosure also provides a delay distribution method 1400, which can be applied to the delay distribution circuit 1200 in any of the above embodiments. The delay distribution circuit 1200 includes an adjustable digital delay circuit 1210, a first delay reference circuit 1220, a second delay reference circuit 1230, an analog delay circuit 1240, a phase comparison circuit 1250, and a control circuit 1260. The delay distribution method 1400 includes step 1410-step 1450.

Step 1410, the adjustable digital delay circuit 1210 delays a zeroth delay signal CLK0 by m times a preset duration to generate an m-th delay signal CLKm. The preset duration is a duration that each digital delay unit in the adjustable digital delay circuit 1210 delays received signals. The m times the preset duration is a digital delay duration T_{DIG}.

Step 1420, the first delay reference circuit 1220, the analog delay circuit 1240, and the second delay reference circuit 1230 respectively delay the m-th delay signal CLKm by a first reference duration T₁, an analog delay duration T_{ANA} and a second reference duration T₂ to generate a first clock signal CLKA′, a second clock signal CLKA, and a third clock signal CLKA″. The preset duration is less than the first reference duration T₁ and greater than the second reference duration T₂.

Step 1430, the phase comparison circuit 1250 generates a first phase signal PH′ and a second phase signal PH″ according to the first clock signal CLKA′, the second clock signal CLKA, and the third clock signal CLKA″. The first phase signal PH′ indicates a numerical relationship between the first reference duration T₁ and the analog delay duration T_{ANA}, the second phase signal PH″ indicates a numerical relationship between the second reference duration T₂ and the analog delay duration T_{ANA}.

Step 1440, according to the first phase signal PH′ and the second phase signal PH″, the control circuit 1260 generates multiple control signals S₁, S₂, . . . , Sₙ to control the number of digital delay units connected in the adjustable digital delay circuit 1210, to adjust the digital delay duration T_{DIG}, thereby adjusting the analog delay duration T_{ANA} to obtain an adjusted analog delay duration.

Step 1450, when the adjusted analog delay duration is within a preset duration range, the analog delay circuit 1240 outputs an adjusted second clock signal CLKB.

The delay distribution circuit and the delay distribution method can not only ensure that the adjusted analog delay duration is within the preset duration range, but also ensure that the adjusted analog delay duration is as small as possible, so that when the delay distribution circuit is applied to other circuits, the duration range that the analog delay circuit can delay the subsequent signals is as large as possible. In addition, by jointly delaying the signals through the adjustable digital delay circuit and the analog delay circuit, on the one hand, because the duration delayed by the analog delay circuit for the signals is continuously adjustable, the duration delayed by the delay-locked loop circuit for the signals is also continuously adjustable, which avoids the time jump caused by using a single digital delay circuit to delay the signals, thereby improving the delay accuracy. On the other hand, it can reduce the number of digital delay units connected in the adjustable digital delay circuit, thereby reducing power consumption and improving chip performance.

The first phase comparator 1300 is coupled to the delay distribution circuit 1200, and is configured to perform phase comparison on the adjusted second clock signal CLKB and the reference clock signal CLK_REF to generate a first signal PH_{H1} and a second signal PH_{H2}.

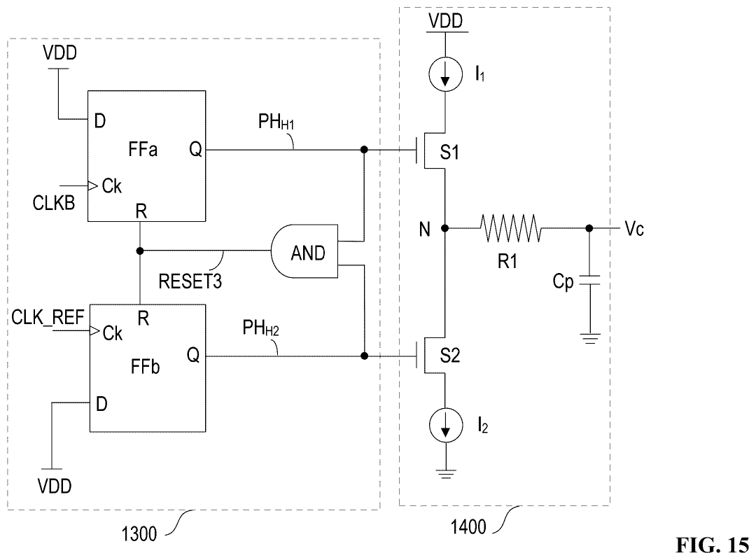

In an embodiment, as shown in FIG. 15, the first phase comparator 1300 includes a flip-flop FFa, a flip-flop FFb, and an AND gate AND. A clock end Ck of the flip-flop FFa receives the adjusted second clock signal CLKB, an input end D of the flip-flop FFa receives a power supply voltage VDD, a clock end Ck of the flip-flop FFb receives the reference clock signal CLK_REF, and an input end D of the flip-flop FFb receives the power supply voltage VDD, an output end Q of the flip-flop FFa is coupled to a first input end of the AND gate AND, an output end Q of the flip-flop FFb is coupled to a second input end of the AND gate AND, and an output end of the AND gate AND is coupled to a reset end R of the flip-flop FFa and a reset end R of the flip-flop FFb to output the reset signal RESET3. In the embodiment, both the flip-flop FFa and the flip-flop FFb are triggered at the rising edges. In other embodiments, those skilled in the art can simply replace the circuit to realize the function of the circuit when the flip-flop FFa and the flip-flop FFb are triggered at the falling edges.

The following will introduce three cases in which the first phase comparator 1300 operates based on the phase relationship between the adjusted second clock signal CLKB and the reference clock signal CLK_REF.

In the first case: the adjusted second clock signal CLKB is ahead of the reference clock signal CLK_REF

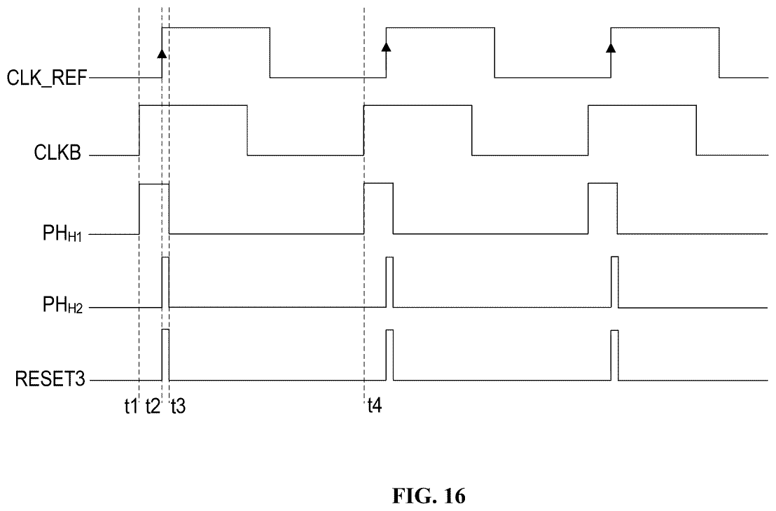

Combining with FIG. 15 and FIG. 16, before time t1, the first signal PH_{H1}, the second signal PH_{H2}, and the reset signal RESET3 are all at a low level. At time t1, a rising edge of the adjusted second clock signal CLKB arrives, the flip-flop FFa is triggered, so that the first signal PH_{H1} output from the output end Q of the flip-flop FFa jumps from a low level to a high level. Because the flip-flop FFb is not triggered, the second signal PH_{H2} output from the output end Q of the flip-flop FFb continues to be at a low level. Therefore, the reset signal RESET3 also continues to be at a low level. At time t2, the flip-flop FFb is triggered, then the second signal PH_{H2} jumps from a low level to a high level. At this time, the reset signal RESET3 jumps from a low level to a high level to make the flip-flop FFa and the flip-flop FFb be reset (that is, at time t3, the first signal PH_{H1} and the second signal PH_{H2} jump from a high level to a low level), thereby making the reset signal RESET3 jump from a high level to a low level. Before the next rising edge of the adjusted second clock signal CLKB arrives, the first signal PH_{H1}, the second signal PH_{H2}, and the reset signal RESET3 are all at a low level.

In the second case: the adjusted second clock signal CLKB lags behind the reference clock signal CLK_REF

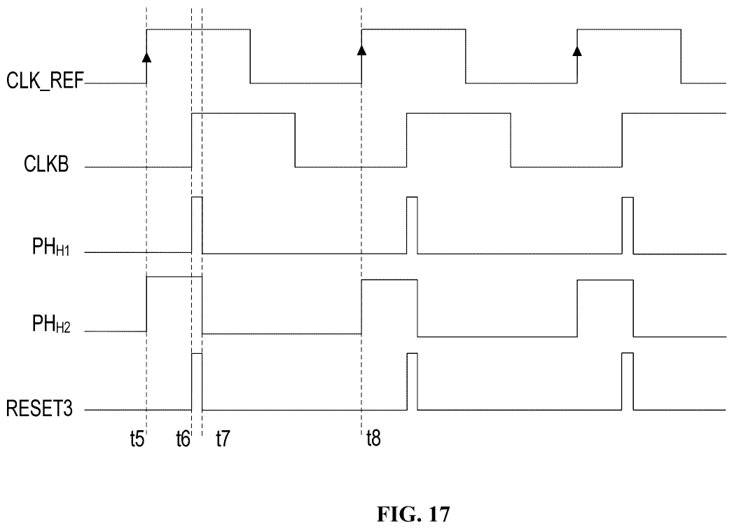

Combining with FIG. 15 and FIG. 17, before time t5, the first signal PH_{H1}, the second signal PH_{H2}, and the reset signal RESET3 are all at a low level. At time t5, a rising edge of the reference clock signal CLK_REF arrives, the flip-flop FFb is triggered, so that the second signal PH_{H2} jumps from a low level to a high level. Because the flip-flop FFa is not triggered, the first signal PH_{H1} continues to be at a low level. Therefore, the reset signal RESET3 also continues to be at a low level. At time t6, the flip-flop FFa is triggered, then the first signal PH_{H1} jumps from a low level to a high level. At this time, the reset signal RESET3 jumps from a low level to a high level to make the flip-flop FFa and the flip-flop FFb be reset (that is, at time t7, the first signal PH_{H1} and the second signal PH_{H2} jump from a high level to a low level), thereby making the reset signal RESET3 jump from a high level to a low level. Before the next rising edge of the reference clock signal CLK_REF arrives, the first signal PH_{H1}, the second signal PH_{H2}, and the reset signal RESET3 are all at a low level.

In the third case: the adjusted second clock signal CLKB is synchronized with the reference clock signal CLK_REF

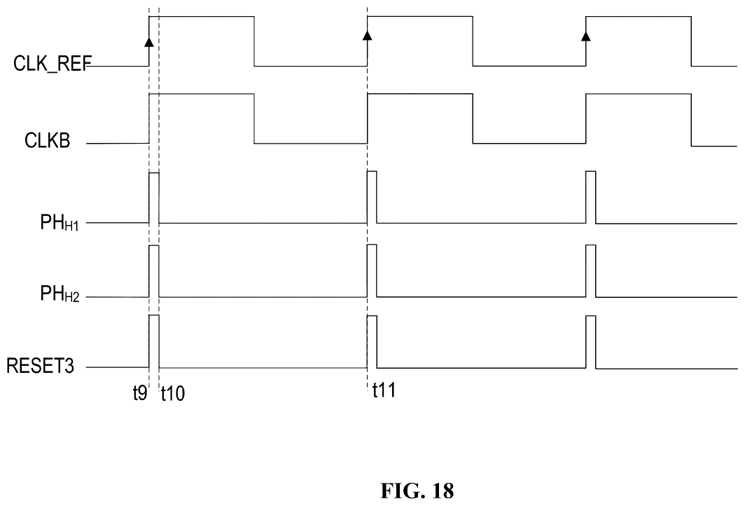

Combining with FIG. 15 and FIG. 18, before time t9, the first signal PH_{H1}, the second signal PH_{H2}, and the reset signal RESET3 are all at a low level. At time t9, because rising edges of the reference clock signal CLK_REF and the adjusted second clock signal CLKB simultaneously arrive, the flip-flop FFa and the flip-flop FFb are simultaneously triggered, that is, both the first signal PH_{H1} and the second signal PH_{H2} jump from a low level to a high level. Therefore, the reset signal RESET3 also jumps from a low level to a high level to make the flip-flop FFa and the flip-flop FFb be reset (that is, at time t10, the first signal PH_{H1} and the second signal PH_{H2} jump from a high level to a low level), thereby making the reset signal RESET3 jump from a high level to a low level at time t10. Before the next rising edges of the reference clock signal CLK REF and the adjusted second clock signal CLKB arrive, the first signal PH_{H1}, the second signal PH_{H2}, and the reset signal RESET3 are all at a low level.

The voltage generation circuit 1400 is coupled to the first phase comparator 1300, and is configured to generate a regulation voltage Vc based on the first signal PH_{H1} and the second signal PH_{H2}, to readjust the adjusted analog delay duration until a twice-adjusted second clock signal output from the delay distribution circuit 1200 is synchronized with the reference clock signal CLK_REF.

In an embodiment, as shown in FIG. 15, the voltage generation circuit 1400 includes a first current source I₁, switches S1 and S2, a second current source I₂, a resistor R₁, and a capacitor Cp. The first current source I₁, switches S1 and S2, and the second current source I₂ are connected in sequence. The other end of the first current source I₁ is connected to the power supply voltage VDD, and the other end of the second current source I₂ is grounded. A control end of the switch S1 is coupled to the output end Q of the flip-flop FFa to receive the first signal PH_{H1}, and a control end of the switch S2 is coupled to the output end Q of the flip-flop FFb to receive the second signal PH_{H2}. The switch S1 is coupled to the switch S2 to form a connection point N. A first end of the resistor R₁ is coupled to the connection point N, and a second end of the resistor R₁ is coupled to a first end of the capacitor Cp to generate the regulation voltage Vc. A second end of the capacitor Cp is grounded. Switches S1 and S2 can be MOS transistors, junction field-effect transistors, triodes, etc., as long as they can be turned on/off according to the level state. In an embodiment, switches S1 and S2 are NMOS transistors.

The working principle of the voltage generation circuit 1400 will be introduced in the following three cases:

For the first case, as shown in FIG. 15 and FIG. 16, from time t1 to time t2, the switch S1 is turned on and the switch S2 is turned off, to make the capacitor Cp charge with a first constant current, thereby increasing a voltage value of the regulation voltage Vc. From time t2 to time t3, both switches S1 and S2 are turned on, which is an instantaneous state (so it can be considered that the capacitor Cp continues to be charged with the first constant current), to continue to increase the voltage value of the regulation voltage Vc. From time t3 to time t4, the switch S1 and the switch S2 are turned off to make the capacitor Cp neither charge nor discharge, thereby making the voltage value of the regulation voltage Vc remain unchanged. In summary, if the adjusted second clock signal CLKB is ahead of the reference clock signal CLK_REF, the voltage value of the regulation voltage Vc will increase.

For the second case, as shown in FIG. 15 and FIG. 17, from time t5 to time t6, the switch S1 is turned off and the switch S2 is turned on, to make the capacitor Cp discharge with a second constant current, thereby reducing the voltage value of the regulation voltage Vc. From time t6 to time t7, both switches S1 and S2 are turned on, which is an instantaneous state (so it can be considered that the capacitor Cp continues to be discharged with the second constant current), to continue to reduce the voltage value of the regulation voltage Vc. From time t7 to time t8, the switch S1 and the switch S2 are both turned off, to make the capacitor Cp neither charge nor discharge, thereby making the voltage value of the regulation voltage Vc remain unchanged. In summary, if the adjusted second clock signal CLKB lags behind the reference clock signal CLK_REF, the voltage value of the regulation voltage Vc will reduce.

For the third case, as shown in FIG. 15 and FIG. 18, from time t9 to time t10, the switches S1 and S2 are simultaneously turned on, which is an instantaneous state (so it can be considered that the capacitor Cp neither charges nor discharges), to make the voltage value of the regulation voltage Vc remain unchanged. From time t10 to time t11, the switch S1 and the switch S2 are both turned off, which causes the capacitor Cp to neither charge nor discharge, thereby keeping the voltage value of the regulation voltage Vc remain unchanged. In summary, if the adjusted second clock signal CLKB is synchronized with the reference clock signal CLK_REF, the voltage value of the regulation voltage Vc will remain unchanged.

Referring to FIG. 15 and FIG. 1, the regulation voltage Vc is fed back to the analog delay circuit 1240 to adjust the adjusted analog delay duration. When the voltage value of the regulation voltage Vc increases, the capacitance values of the first MOS capacitor C1 and the second MOS capacitor C2 also increase to increase the charging and discharging time required by the first MOS capacitor C1 and the second MOS capacitor C2, thereby increasing the adjusted analog delay duration. This results in the twice-adjusted second clock signal being synchronized with the reference clock signal CLK REF. When the voltage value of the regulation voltage Vc reduces, the capacitance values of the first MOS capacitor C1 and the second MOS capacitor C2 also reduce to reduce the charging and discharging time required by the first MOS capacitor C1 and the second MOS capacitor C2, thereby reducing the adjusted analog delay duration. This results in the twice-adjusted second clock signal being synchronized with the reference clock signal CLK_REF. When the voltage value of the regulation voltage Vc remains unchanged, the charging and discharging time required by the first MOS capacitor C1 and the second MOS capacitor C2 remains unchanged, thereby making the adjusted analog delay duration remain unchanged. That is, the adjusted second clock signal CLKB continues to be synchronized with the reference clock signal CLK_REF.

In summary, combining with FIGS. 1, 2A, 3A, 4-6, 7A, and 8-18, the working principle of the delay-locked loop circuit 1000 is as follows:

According to the working principle of the delay distribution circuit 1200 described above, the delay distribution circuit 1200 finally outputs the adjusted second clock signal CLKB. At the same time, the adjusted second clock signal CLKB is input to the first phase comparator 1300 in FIG. 1.

The first phase comparator 1300 performs phase comparison on the adjusted second clock signal CLKB and the reference clock signal CLK_REF, to generate the first signal PH_{H1} and the second signal PH_{H2}.

If the timing diagram of the first signal PH_{H1} and the second signal PH_{H2} is as shown in FIG. 17, the regulation voltage Vc generated by the voltage generation circuit 1400 reduces according to the first signal PH_{H1} and the second signal PH_{H2}.

The analog delay circuit 1240, under the control of a reduced regulation voltage, delay the (m+1)-th delay signal CLK(m+1) by the twice-adjusted analog delay duration to generate a twice-adjusted second clock signal. The twice-adjusted analog delay duration is less than the adjusted analog delay duration.

The first phase comparator 1300 compares the twice-adjusted second clock signal with the reference clock signal CLK_REF, to generate a new first signal and a new second signal.

If the timing diagram of the new first signal and the new second signal is as shown in FIG. 18, the regulation voltage Vc generated by the voltage generation circuit 1400 remains unchanged according to the new first signal and the new second signal, to make the twice-adjusted analog delay duration remain unchanged. At this time, the twice-adjusted second clock signal is synchronized with the reference clock signal CLK_REF, so the delay-locked loop circuit 1000 reaches a locked state.

In above embodiments, the adjusted second clock signal CLKB lags behind the reference clock signal CLK_REF after one adjustment (by increasing the number of digital delay units connected in the adjustable digital delay circuit), and the twice-adjusted second clock signal can be synchronized with the reference clock signal CLK REF after one adjustment (by reducing the adjusted analog delay duration). In addition, the adjusted second clock signal CLKB may be the second clock signal CLKA, the twice-adjusted second clock signal may be the adjusted second clock signal CLKB.

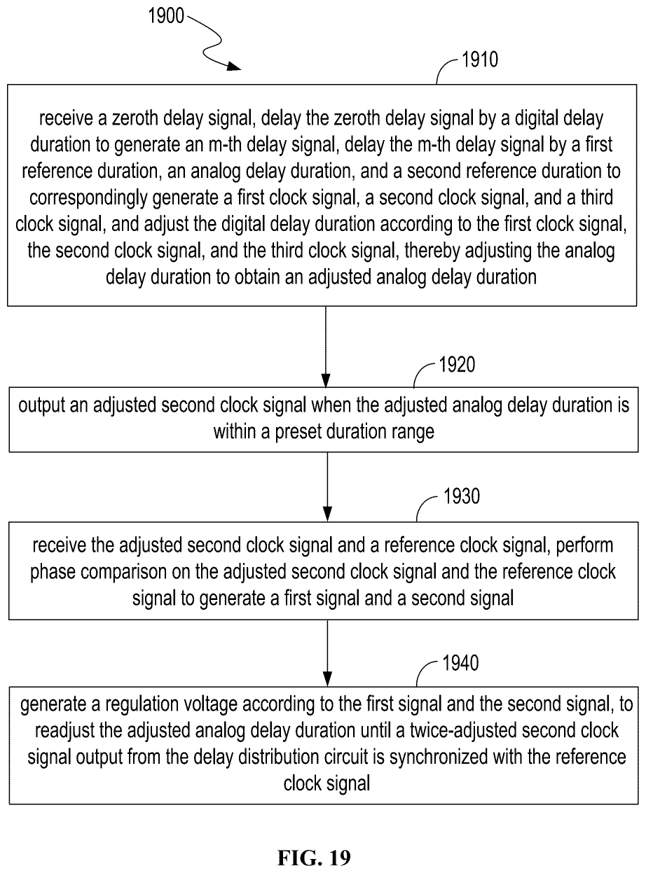

As shown in FIG. 19, the disclosure also provides a delay-locked loop method 1900, which is applied to the delay-locked loop circuit 1000. The delay-locked loop circuit 1000 includes a delay distribution circuit 1200, a first phase comparator 1300, and a voltage generation circuit 1400. The delay-locked loop method 1900 includes step 1910-step 1940.

Step 1910, receiving, using the delay distribution circuit 1200, a zeroth delay signal CLK0, delaying the zeroth delay signal CLK0 by a digital delay duration T DIG to generate an m-th delay signal CLKm, delaying the m-th delay signal CLKm by a first reference duration T₁, an analog delay duration T_{ANA}, and the second reference duration T₂ to correspondingly generate a first clock signal CLKA′, a second clock signal CLKA, and a third clock signal CLKA″, and adjusting the digital delay duration T_{DIG} according to the first clock signal CLKA′, the second clock signal CLKA, and the third clock signal CLKA″, thereby adjusting the analog delay duration T_{ANA} to obtain an adjusted analog delay duration. The first reference duration T₁ is greater than the second reference duration T₂.

Step 1920, outputting, using the delay distribution circuit 1200, an adjusted second clock signal CLKB when the adjusted analog delay duration is within a preset duration range. The preset duration range is between the second reference duration T₂ and the first reference duration T₁.

Step 1930, receiving, using the first phase comparator 1300, the adjusted second clock signal CLKB and the reference clock signal CLK_REF, performing phase comparison on the reference clock signal CLK_REF and the adjusted second clock signal CLKB to generate a first signal PH_{H1} and a second signal PH_{H2}.

Step 1940, generating, using the voltage generation circuit 1400, a regulation voltage Vc according to the first signal PH_{H1} and the second signal PH_{H2}, to readjust the adjusted analog delay duration until a twice-adjusted second clock signal output from the delay distribution circuit 1200 is synchronized with the reference clock signal CLK_REF.

The delay-locked loop circuit and the delay-locked loop method preliminarily adjust the analog delay duration and the digital delay duration, so that the adjusted analog delay duration is within the preset duration range, thereby making the subsequent analog delay to have a large adjustable range. Then, the regulation voltage is used to readjust the adjusted analog delay duration, so that the twice-adjusted second clock signal is synchronized with the reference clock signal. This approach can reduce the number of phase comparison between the adjusted second clock signal and the reference clock signal, thereby achieving rapid locking of the delay-locked loop circuit. In addition, by jointly delaying the signals through the adjustable digital delay circuit and the analog delay circuit, on the one hand, because the duration delayed by the analog delay circuit for the signals is continuously adjustable, the duration delayed by the delay-locked loop circuit for the signals is also continuously adjustable, which avoids the time jump caused by using a single digital delay circuit to delay the signals, thereby improving the delay accuracy. On the other hand, it can reduce the number of digital delay units connected in the adjustable digital delay circuit, thereby reducing power consumption and improving chip performance.

While the foregoing description and drawings represent embodiments of the disclosure, it will be understood that various additions, modifications, and substitutions may be made therein without departing from the spirit and scope of the principles of the disclosure as defined in the accompanying claims. One skilled in the art will appreciate that the disclosure may be used with many modifications of form, structure, arrangement, proportions, materials, elements, and components and otherwise, used in the practice of the disclosure, which are particularly adapted to specific environments and operative requirements without departing from the principles of the disclosure. The presently disclosed embodiments are therefore to be considered in all respects as illustrative and not restrictive, the scope of the disclosure being indicated by the appended claims and their legal equivalents, and not limited to the foregoing description.

What is claimed is:

1. A delay-locked loop circuit, at least comprising:
a delay distribution circuit, configured to receive a zeroth delay signal, delay the zeroth delay signal by a digital delay duration to generate an m-th delay signal, delay the m-th delay signal by a first reference duration, an analog delay duration, and a second reference duration to correspondingly generate a first clock signal, a second clock signal, and a third clock signal, adjust the digital delay duration according to the first clock signal, the second clock signal, and the third clock signal, thereby adjusting the analog delay duration to obtain an adjusted analog delay duration, and output an adjusted second clock signal when the adjusted analog delay duration is within a preset duration range, wherein the first reference duration is greater than the second reference duration, the preset duration range is between the second reference duration and the first reference duration;
a first phase comparator, coupled to the delay distribution circuit, configured to receive the adjusted second clock signal and a reference clock signal, and perform phase comparison on the adjusted second clock signal and the reference clock signal to generate a first signal and a second signal; and
a voltage generation circuit, coupled to the first phase comparator, configured to generate a regulation voltage according to the first signal and the second signal, to readjust the adjusted analog delay duration until a twice-adjusted second clock signal output from the delay distribution circuit is synchronized with the reference clock signal.

2. The delay-locked loop circuit of claim 1, wherein when the second clock signal is ahead of or synchronized with the third clock signal, the digital delay duration is reduced, thereby increasing the analog delay duration; when the second clock signal is ahead of the first clock signal and the second clock signal lags behind the third clock signal, the digital delay duration remains unchanged so that the analog delay duration also remains unchanged; when the second clock signal lags behind or is synchronized with the first clock signal and the second clock signal lags behind the third clock signal, the digital delay duration is increased, thereby reducing the analog delay duration.

3. The delay-locked loop circuit of claim 1, wherein the delay distribution circuit comprises:
an adjustable digital delay circuit, configured to receive the zeroth delay signal, delay the zeroth delay signal by m times a preset duration to generate the m-th delay signal, wherein the preset duration is a duration that each digital delay unit in the adjustable digital delay circuit delays received signals, the m times the preset duration is the digital delay duration, the preset duration is less than the first reference duration and is greater than the second reference duration;
a first delay reference circuit, coupled to the adjustable digital delay circuit, configured to delay the m-th delay signal by the first reference duration to generate the first clock signal;
an analog delay circuit, coupled to the adjustable digital delay circuit, configured to delay the m-th delay signal by the analog delay duration to generate the second clock signal, and readjust the adjusted analog delay duration to generate the twice-adjusted second clock signal according to the regulation voltage; and
a second delay reference circuit, coupled to the adjustable digital delay circuit, configured to delay the m-th delay signal by the second reference duration to generate the third clock signal.

4. The delay-locked loop circuit of claim 3, wherein the delay distribution circuit further comprises:
a phase comparison circuit, respectively coupled to the first delay reference circuit and the analog delay circuit, configured to generate a first phase signal and a second phase signal according to the first clock signal, the second clock signal, and the third clock signal, wherein the first phase signal indicates a numerical relationship between the first reference duration and the analog delay duration, the second phase signal indicates a numerical relationship between the second reference duration and the analog delay duration; and
a control circuit, coupled between the phase comparison circuit and the adjustable digital delay circuit, configured to generate a plurality of control signals according to the first phase signal and the second phase signal, wherein the plurality of control signals control the number of digital delay units connected in the adjustable digital delay circuit to adjust the digital delay duration.

5. The delay-locked loop circuit of claim 4, wherein
when the first phase signal and the second phase signal jointly indicate that the analog delay duration is not greater than the second reference duration, the plurality of control signals control the number of digital delay units connected in the adjustable digital delay circuit to be reduced to reduce the digital delay duration, thereby increasing the analog delay duration;
when the first phase signal and the second phase signal jointly indicate that the analog delay duration is less than the first reference duration and greater than the second reference duration, the plurality of control signals control the number of digital delay units connected in the adjustable digital delay circuit to remain unchanged, to make the digital delay duration remain unchanged, thereby making the analog delay duration also remain unchanged;
when the first phase signal and the second phase signal jointly indicate that the analog delay duration is not less than the first reference duration, the plurality of control signals control the number of digital delay units connected in the adjustable digital delay circuit to be increased to increase the digital delay duration, thereby reducing the analog delay duration.

6. The delay-locked loop circuit of claim 4, wherein the adjustable digital delay circuit comprises a plurality of digital delay units coupled in sequence and a plurality of switch circuits set correspondingly, wherein each digital delay unit is correspondingly coupled to a switch circuit, an m-th control signal of the plurality of control signals controls an m-th switch circuit of the plurality of switch circuits to be turned on, other control signals other than the m-th control signal control other switch circuits other than the m-th switch circuit to be turned off, to make m digital delay units delay the zeroth delay signal to generate the m-th delay signal, thereby respectively transmitting the m-th delay signal to the analog delay circuit and the first delay reference circuit.

7. The delay-locked loop circuit of claim 4, wherein the phase comparison circuit comprises:
a second phase comparator, respectively coupled to the first delay reference circuit, the second delay reference circuit, and the analog delay circuit, configured to control the first phase signal or the second phase signal to perform a first level conversion according to a phase relationship between the first clock signal and the second clock signal, and/or a phase relationship between the second clock signal and the third clock signal; and
a reset circuit, coupled to the second phase comparator, configured to generate a reset signal to control the first phase signal or the second phase signal to perform a second level conversion, according to the first phase signal, the second phase signal, the second clock signal, and the third clock signal.

8. The delay-locked loop circuit of claim 7, wherein
under a condition that the second clock signal is ahead of or synchronized with the third clock signal, the second phase signal jumps from a first level to a second level when a first rising edge of the second clock signal arrives, and the reset signal jumps from a first level to a second level when a first rising edge of the third clock signal arrives, thereby controlling the second phase signal to jump from a second level to a first level;
under a condition that the second clock signal is ahead of the first clock signal and the second clock signal lags behind the third clock signal, the first phase signal, the second phase signal, and the reset signal are always at a first level;
under a condition that the second clock signal lags behind or is synchronized with the first clock signal and the second clock signal lags behind the third clock signal, the first phase signal jumps from a first level to a second level when a first rising edge of the first clock signal arrives, and the reset signal jumps from a first level to a second level when a first rising edge of the second clock signal arrives, thereby controlling the first phase signal to jump from a second level to a first level.

9. The delay-locked loop circuit of claim 7, wherein the second phase comparator comprises a first flip-flop, a first NOT gate, a second NOT gate, a first NOR gate, a second flip-flop, a third NOT gate, a fourth NOT gate, and a second NOR gate, wherein an input end of the first NOT gate receives the second clock signal, an output end of the first NOT gate is coupled to an input end of the first flip-flop, a clock end of the first flip-flop receives the first clock signal, an output end of the first flip-flop is coupled to the reset circuit to output the first phase signal to the reset circuit, an first input end of the second NOR gate is coupled to an output end of the first flip-flop, a second input end of the second NOR gate is coupled to the reset circuit to receive the reset signal generated by the reset circuit, an output end of the second NOR gate is coupled to an input end of the fourth NOT gate, an output end of the fourth NOT gate is coupled to a reset end of the second flip-flop, an input end of the third NOT gate receives the third clock signal, an output end of the third NOT gate is coupled to an input end of the second flip-flop, a clock end of the second flip-flop receives the second clock signal, a first input end of the first NOR gate is coupled to an output end of the second flip-flop, a second input end of the first NOR gate is coupled to the reset circuit to receive the reset signal, an output end of the second flip-flop is coupled to the reset circuit to output the second phase signal to the reset circuit, an output end of the first NOR gate is coupled to an input end of the second NOT gate, and an output end of the second NOT gate is coupled to a reset end of the first flip-flop.

10. The delay-locked loop circuit of claim 7, wherein the reset circuit comprises a first set of flip-flops, a second set of flip-flops, a third NOR gate, and a fifth NOT gate,
wherein in the first set of flip-flops, an input end of a first flip-flop receives the first phase signal, a clock end of each flip-flop receives the second clock signal, an output end of a last flip-flop is coupled to a reset end of each flip-flop, and an output end of each flip-flop is coupled to an input end of the third NOR gate,
wherein in the second set of flip-flops, an input end of a first flip-flop receives the second phase signal, a clock end of each flip-flop receives the third clock signal, an output end of a last flip-flop is coupled to a reset end of each flip-flop, and an output end of each flip-flop is coupled to an input end of the third NOR gate,
wherein an output end of the third NOR gate is coupled to the fifth NOT gate, the fifth NOT gate outputs the reset signal, and the plurality of flip-flops are sequentially triggered according to a plurality of edges of the second clock signal.

11. The delay-locked loop circuit of claim 4, wherein the phase comparison circuit comprises:
a second phase comparator, coupled to the first delay reference circuit and the analog delay circuit, configured to control the first phase signal to perform a first level conversion according to a phase relationship of the first clock signal and the second clock signal;
a voltage comparison circuit, configured to receive the regulation voltage and a limit voltage, compare the regulation voltage and the limit voltage to generate the second phase signal, wherein the limit voltage indicates the minimum duration that the analog delay circuit delays received signals, and the regulation voltage indicates the magnitude of the analog delay duration, wherein when the regulation voltage is not greater than the limit voltage, the second phase signal jumps from a first level to a second level; and
a reset circuit, coupled to the second phase comparator, the voltage comparison circuit, the second delay reference circuit, and the analog delay circuit, configured to generate a reset signal to control the first phase signal to perform a second level conversion according to the second clock signal, the third clock signal, the first phase signal, and the second phase signal.

12. The delay-locked loop circuit of claim 11, wherein under a condition that the first clock signal is ahead of or synchronized with the second clock signal, the first phase signal jumps from a first level to a second level when a first rising edge of the first clock signal arrives, and the reset signal jumps from a first level to a second level when a first rising edge of the second clock signal arrives, thereby controlling the first phase signal to jump from a second level to a first level; under a condition that the first clock signal lags behind the second clock signal, the first phase signal and the reset signal are always at a first level.

13. The delay-locked loop circuit of claim 11, wherein the second phase comparator comprises a first flip-flop, a first NOT gate, a second NOT gate, a first NOR gate, a second flip-flop, a third NOT gate, a fourth NOT gate, and a second NOR gate, wherein an input end of the first NOT gate receives the second clock signal, an output end of the first NOT gate is coupled to an input end of the first flip-flop, a clock end of the first flip-flop receives the first clock signal, an output end of the first flip-flop is coupled to the reset circuit to output the first phase signal to the reset circuit, an first input end of the second NOR gate is coupled to an output end of the first flip-flop, a second input end of the second NOR gate is coupled to the reset circuit to receive the reset signal generated by the reset circuit, an output end of the second NOR gate is coupled to an input end of the fourth NOT gate, an output end of the fourth NOT gate is coupled to a reset end of the second flip-flop, an input end of the third NOT gate receives the first clock signal, an output end of the third NOT gate is coupled to an input end of the second flip-flop, a clock end of the second flip-flop receives the second clock signal, a first input end of the first NOR gate is coupled to an output end of the second flip-flop, a second input end of the first NOR gate is coupled to the reset circuit to receive the reset signal, an output end of the first NOR gate is coupled to an input end of the second NOT gate, and an output end of the second NOT gate is coupled to a reset end of the first flip-flop.

14. The delay-locked loop circuit of claim 4, wherein the control circuit comprises a plurality of control units,
wherein each control unit has the same configuration, and an m-th control unit comprises a first AND gate, a second AND gate, an NOR gate, a sixth NOT gate, a third flip-flop, and an m-th pulse generator,
wherein an input end of the first AND gate receives the first phase signal and an (m−1)-th control signal, an input end of the second AND gate receives the second phase signal and an (m+1)-th control signal, an output end of the first AND gate and an output end of the second AND gate are coupled to two input ends of the NOR gate, an output end of the NOR gate is coupled to an input end of the sixth NOT gate, an output end of the sixth NOT gate is coupled to an clock end of the third flip-flop, an input end of the third flip-flop receives a high level, an output end of the third flip-flop outputs an m-th control signal, a reset end of the third flip-flop is coupled to the m-th pulse generator; and
wherein the m-th pulse generator comprises a first delayer, a second delayer, a seventh NOT gate, an eighth NOT gate, a first NAND gate, a second NAND gate, and a third NAND gate; a first input end of the first NAND gate receives the (m−1)-th control signal, a second input end of the first NAND gate receives a first logic signal; a first input end of the second NAND gate receives the (m+1)-th control signal, a second input end of the second NAND gate receives a second logic signal, two input ends of the third NAND gate are coupled to an output end of the first NAND gate and an output end of the second NAND gate, and an output end of the third NAND gate outputs a pulse signal, wherein the (m−1)-th control signal becomes the first logic signal after passing through the first delayer and the seventh NOT gate in sequence, the (m+1)-th control signal becomes the second logic signal after passing through the second delayer and the eighth NOT gate in sequence.

15. The delay-locked loop circuit of claim 1, wherein when the adjusted second clock signal is ahead of the reference clock signal, a voltage value of the regulation voltage is increased to increase the adjusted analog delay duration; when the adjusted second clock signal lags behind the reference clock signal, a voltage value of the regulation voltage is reduced to reduce the adjusted analog delay duration; when the adjusted second clock signal is synchronized with the reference clock signal, a voltage value of the regulation voltage remains unchanged to make the adjusted analog delay duration remain unchanged.

16. A delay-locked loop method, applied to a delay-locked loop circuit, the delay-locked loop circuit comprising a delay distribution circuit, a first phase comparator, and a voltage generation circuit, and the delay-locked loop method comprising:
receiving, using the delay distribution circuit, a zeroth delay signal, delaying the zeroth delay signal by a digital delay duration to generate an m-th delay signal, delaying the m-th delay signal by a first reference duration, an analog delay duration, and a second reference duration to correspondingly generate a first clock signal, a second clock signal, and a third clock signal, and adjusting the digital delay duration according to the first clock signal, the second clock signal, and the third clock signal, thereby adjusting the analog delay duration to obtain an adjusted analog delay duration, wherein the first reference duration is greater than the second reference duration;
outputting, using the delay distribution circuit, an adjusted second clock signal when the adjusted analog delay duration is within a preset duration range, wherein the preset duration range is between the second reference duration and the first reference duration;
receiving, using the first phase comparator, the adjusted second clock signal and a reference clock signal, performing phase comparison on the adjusted second clock signal and the reference clock signal to generate a first signal and a second signal; and
generating, using the voltage generation circuit, a regulation voltage according to the first signal and the second signal, to readjust the adjusted analog delay duration until a twice-adjusted second clock signal output from the delay distribution circuit is synchronized with the reference clock signal.

17. The delay-locked loop method of claim 16, wherein the delay distribution circuit comprises an adjustable digital delay circuit, a first delay reference circuit, an analog delay circuit, and a second delay reference circuit, wherein the delay-locked loop method comprises:
receiving, using the adjustable digital delay circuit, the zeroth delay signal, delaying the zeroth delay signal by m times a preset duration to generate the m-th delay signal, wherein the preset duration is a duration that each digital delay unit in the adjustable digital delay circuit delays received signals, the m times the preset duration is the digital delay duration, the preset duration is less than the first reference duration and is greater than the second reference duration;
delaying, using the first delay reference circuit, the m-th delay signal by the first reference duration to generate the first clock signal;
delaying, using the analog delay circuit, the m-th delay signal by the analog delay duration to generate the second clock signal, and readjusting the adjusted analog delay duration to generate the twice-adjusted second clock signal according to the regulation voltage; and
delaying, using a second delay reference circuit, the m-th delay signal by the second reference duration to generate the third clock signal.

18. The delay-locked loop method of claim 17, wherein the delay distribution circuit further comprises a phase comparison circuit and a control circuit, and the delay-locked loop method comprises:
generating, using the phase comparison circuit, a first phase signal and a second phase signal according to the first clock signal, the second clock signal, and the third clock signal, wherein the first phase signal indicates a numerical relationship between the first reference duration and the analog delay duration, the second phase signal indicates a numerical relationship between the second reference duration and the analog delay duration; and
generating, using the control circuit, a plurality of control signals according to the first phase signal and the second phase signal, wherein the plurality of control signals control the number of digital delay units connected in the adjustable digital delay circuit to adjust the digital delay duration.

19. The delay-locked loop method of claim 18, wherein
when the first phase signal and the second phase signal jointly indicate that the analog delay duration is not greater than the second reference duration, the plurality of control signals control the number of digital delay units connected in the adjustable digital delay circuit to be reduced to reduce the digital delay duration, thereby increasing the analog delay duration;
when the first phase signal and the second phase signal jointly indicate that the analog delay duration is less than the first reference duration and greater than the second reference duration, the plurality of control signals control the number of digital delay units connected in the adjustable digital delay circuit to remain unchanged, to make the digital delay duration remain unchanged, thereby making the analog delay duration also remain unchanged;
when the first phase signal and the second phase signal jointly indicate that the analog delay duration is not less than the first reference duration, the plurality of control signals control the number of digital delay units connected in the adjustable digital delay circuit to be increased to increase the digital delay duration, thereby reducing the analog delay duration.

20. The delay-locked loop method of claim 18, wherein the phase comparison circuit comprises a second phase comparator and a reset circuit, and the delay-locked loop method comprises:
controlling, using the second phase comparator, the first phase signal or the second phase signal to perform a first level conversion according to a phase relationship between the first clock signal and the second clock signal, and/or a phase relationship between the second clock signal and the third clock signal; and
generating, using the reset circuit, the reset signal according to the first phase signal, the second clock signal, the second clock signal, and the third clock signal to control the first phase signal or the second phase signal to perform a second level conversion.

21. The delay-locked loop method of claim 20, wherein
under a condition that the second clock signal is ahead of or synchronized with the third clock signal, the second phase signal jumps from a first level to a second level when a first rising edge of the second clock signal arrives, and the reset signal jumps from a first level to a second level when a first rising edge of the third clock signal arrives, thereby controlling the second phase signal to jump from a second level to a first level;
under a condition that the second clock signal is ahead of the first clock signal and the second clock signal lags behind the third clock signal, the first phase signal, the second phase signal, and the reset signal are always at a first level; and
under a condition that the second clock signal lags behind or is synchronized with the first clock signal and the second clock signal lags behind the third clock signal, the first phase signal jumps from a first level to a second level when a first rising edge of the first clock signal arrives, and the reset signal jumps from a first level to a second level when a first rising edge of the second clock signal arrives, thereby controlling the first phase signal to jump from a second level to a first level.
